(19) United States
(12) Patent Application Publication
(10) Pub. No.: US 2013/0171525 A1
(43) Pub. Date: Jul. 4, 2013

(54) PRODUCTION PROCESS FOR COMPOSITE OXIDE, POSITIVE-ELECTRODE ACTIVE MATERIAL FOR SECONDARY BATTERY AND SECONDARY BATTERY

(71) Applicants: Naoto Yasuda, Kariya-shi (JP); Toru Abe, Kariya-shi (JP); Ryota Isomura, Kariya-shi (JP)

(72) Inventors: Naoto Yasuda, Kariya-shi (JP); Toru Abe, Kariya-shi (JP); Ryota Isomura, Kariya-shi (JP)

(73) Assignee: KABUSHIKI KAISHA TOYOTA JIDOSHOKKI, Kariya-shi, Aichi (JP)

(21) Appl. No.: 13/820,961

(22) PCT Filed: Aug. 6, 2011
(86) PCT No.: PCT/JP2011/004482

§ 371 Date: Mar. 5, 2013

(30) Foreign Application Priority Data
Sep. 9, 2010 (JP) 2010-202222

(51) Int. Cl. H01M 4/1391; H01M 4/131; H01M 4/04; C30B 9/00

(52) U.S. Cl. CPC H01M 4/1391; C30B 9/00; H01M 4/131; H01M 4/0471; H01M 4/0497
USPC 429/224; 423/599; 117/73

(57) ABSTRACT

A production process according to the present invention is a novel production process for composite oxide, production process whose a major product is a lithium-manganese-based oxide that includes at least the following: a lithium (Li) element; and a tetravalent manganese (Mn) element, and lithium-manganese-based oxide whose crystal structure belongs to a layered rock-salt structure;
said composite oxide is obtained via the following:
a molten reaction step of reacting at least the following one another: a metal-containing raw material; and a molten-salt raw material at a melting point of the molten-salt raw material or more,
the metal-containing raw material including one or more kinds of metallic elements in which Mn is essential,
the molten-salt raw material including lithium hydroxide but not including any other compound virtually, and the molten-salt raw material including Li in an amount that exceeds a theoretical composition of Li being included in said composite oxide to be targeted; and
a recovery step of recovering said composite oxide being generated at said molten reaction step.

### TECHNICAL FIELD

The present invention is one which relates to a composite oxide that is employed as a positive-electrode material for lithium-ion secondary battery, and the like, and to a secondary battery that uses that composite oxide.

### BACKGROUND ART

Recently, as being accompanied by the developments of portable electronic devices such as cellular phones and notebook-size personal computers, or as being accompanied by electric automobiles being put into practical use, and the like, small-sized, lightweight and high-capacity secondary batteries have been required. At present, as for high-capacity secondary batteries meeting these demands, non-aqueous secondary batteries have been commercialized, non-aqueous secondary batteries in which lithium cobaltate (e.g., LiCoO₂) and the carbon-based materials are used as the positive-electrode material and negative-electrode material, respectively. Since such a non-aqueous secondary battery exhibits a high energy density, and since it is possible to intend to make it downsize and lightweight, its employment as a power source has been attracting attention in a wide variety of fields. However, since LiCoO₂ is produced with use of Co, one of rare metals, as the raw material, it has been expected that its scarcity as the resource would grow worse from now on. In addition, since Co is expensive, and since its price fluctuates greatly, it has been desired to develop positive-electrode materials that are inexpensive as well as whose supply is stable.

Hence, it has been regarded promising to employ lithium-manganese-oxide-based composite oxides whose constituent elements are inexpensive in terms of the prices as well as which include stably-supplied manganese (Mn) in their basic compositions. Among them, a substance, namely, Li₂MnO₃ has been attracting attention, Li₂MnO₃ which includes tetravalent manganese ions alone but does not include any trivalent manganese ions making a cause of the manganese elution upon charging and discharging. Although it has been believed so far that it is impossible to charge and discharge Li₂MnO₃, it has come to find out that it is possible to charge and discharge it by means of charging it up to 4.8 V, according to recent studies. However, it is needed to further improve Li₂MnO₃ with regard to the charging/discharging characteristics.

In order to improve the charging/discharging characteristics, it has been done actively to develop xLi₂MnO₃.(1−x) LiMeO₂ (where 0<“x”≦1), one of solid solutions between Li₂MnO₃ and LiMeO₂ (where “Me” is a transition metal element). Note that it is feasible to write and express Li₂MnO₃ by a general formula, Li (Li_{0.33}Mn_{0.67}) O₂, as well, and that it is said to belong to the same crystal structure as that of LiMeO₂. Consequently, there arises a case where xLi₂MnO₃.(1−x)LiMeO₂ is set forth as Li_{1.33-y}Mn_{0.67-z}Me_{y+z}O₂ (where 0≦“y”<0.33, and 0≦“z”<0.67), too. However, even any of the two methods for writing it down specify a composite oxide that possesses the same sort of crystal structure.

For example, Patent Literature No. 1 discloses a production process for solid solution between LiMO₂ and Li₂NO₃ (where “M” is one or more kinds that are selected from Mn, Ni, Co and Fe, and “N” is one or more kinds that are selected from Mn, Zr and Ti). This solid solution is obtainable as follows: ammonia water is dropped to a mixed solution, in which salts of respective metallic elements that correspond to “M” and “N” are dissolved, until the pH becomes 7; an Na₂CO₃ solution is further dropped to it in order to deposit “M”-“N”-based composite carbonates; and the resulting “M”-“N”-based composite carbonates are calcined after mixing them with LiOH.H₂O.

Moreover, upon employing a secondary battery including Li₂MnO₃ as the positive-electrode active material, it is needed to activate the positive-electrode active material prior to the employment. However, in a case where a particle diameter of Li₂MnO₃ is large, since only the particles' superficial layer is activated, it is believed that it is necessary to make the particle diameter of Li₂MnO₃ smaller in order to turn Li₂MnO₃ to be employed into an active material serving as battery in the total amount substantially. In other words, it is needed to develop convenient processes for synthesizing fine particles as well. For example, in Patent Literature No. 2, a process for synthesizing nano-order oxide particles is disclosed. In Example No. 3 of Patent Literature No. 2, MnO₂ and Li₂O₂ are added to and are then mixed with a mixture, in which LiOH.H₂O and LiNO₃ are mixed in a molar ratio of 1:1, thereby synthesizing lithium manganate (e.g., LiMn₂O₄), whose manganese has an average oxidation number that is equal to a valence number of 3.5, by turning the mixture into a molten salt after letting the mixture go through a drying step.

A production process for lithium manganate that uses a molten-salt method as mentioned above is disclosed in Patent Literature No. 3 as well. It is set forth in Example No. 1 that a product, which is obtainable by dropping an Mn₂O₃ powder into a 600° C. LiOH molten salt in an argon atmosphere and then cooling them rapidly after reacting them, is LiMnO₂ in which an average oxidation number of the manganese is trivalent. Moreover, in Patent Literature No. 3, the following are set forth: when the reaction atmosphere contains an oxygen gas, a selectivity rate for lithium manganate with layered structure declines; and for the synthesis of lithium manganate with spinel structure, an atmosphere containing oxygen in an amount of 10% or more is need.

### RELATED TECHNICAL LITERATURE

### Patent Literature

Patent Literature No. 1: Japanese Unexamined Patent Publication (KOKAI) Gazette No. 2008-270201;
Patent Literature No. 2: Japanese Unexamined Patent Publication (KOKAI) Gazette No. 2008-105912; and
Patent Literature No. 3: Japanese Unexamined Patent Publication (KOKAI) Gazette No. 2001-192210

### SUMMARY OF THE INVENTION

### Assignment to be Solved by the Invention

As described above, although a fine-particle-shaped lithium-manganese-oxide-based composite oxide including tetravalent Mn alone has been sought for, it is assumed that a particle diameter of a solid solution between LiMO₂ and Li₂NO₃ that is obtainable by the process according to Patent Literature No. 1 would be from several micrometers to several dozen micrometers from the calcining temperature and X-ray diffraction pattern shown in FIG. 6. That is, it is not possible to obtain nano-order fine particles by the process being set forth in Patent Literature No. 1.

In accordance with the production process according to Patent Literature No. 2, although it is possible to produce nano-order fine particles by means of the molten-salt method, it has not been possible yet to make an oxide like Li₂MnO₃ that includes tetravalent Mn alone. In Patent Literature No. 2, the following has been stated: the reaction rate is upgraded by adding an oxide or a peroxide to a mixed molten salt of lithium hydroxide and lithium nitrate by means of heightening the oxide ion (i.e., O²⁻) concentration in the molten salt, and so nano particles with much smaller particle diameters become likely to generate. However, the relationships between the reaction conditions and the compositions or structures of the resulting nano particles are not considered at all.

Moreover, as set forth in Example No. 3 according to Patent Literature No. 2, LiMn₂O₄ (whose Mn's average oxidation number is equal to a valence number of 3.5) is obtainable, even by the molten-salt method, on an order of 1 μm approximately in a case where manganese nitrate is reacted at 650° C. or more within a molten salt of lithium chloride. That is, it has not been possible yet to produce oxides, like Li₂MnO₃ that includes tetravalent Mn alone, as nano-order fine particles.

In Patent Literature No. 3, since the valence number of Mn in the substance (i.e., LiMnO₂), which was synthesized in Example No. 1, was as low as trivalent, it is possible to say that, in Example No. 1, the reaction conditions were not sufficient at all for synthesizing lithium manganese oxides, such as Li₂MnO₃ that includes tetravalent Mn alone. Moreover, in Patent Literature No. 3, no thought extends, not to mention synthesizing lithium manganese oxide that includes tetravalent Mn alone, but up to actively synthesizing lithium manganese oxide furthermore that includes tetravalent Mn alone and which possesses a layered rock-salt structure.

Incidentally, the present inventors have been investigating so far a production process for lithium manganese oxide that includes tetravalent Mn, like Li₂MnO₃, for instance (refer to Japanese Patent Application No. 2009-294080, Japanese Patent Application No. 2010-051676, and the like). Using a mixed molten salt of lithium hydroxide and lithium nitrate makes it possible to make a melting point of the resulting molten salt, and eventually the resultant reaction temperature, a lower temperature comparatively, and thereby fine products are obtainable. On this occasion, they found out that powders of lithium manganese oxide, which possesses a desired structure, are obtainable, depending on a proportion of lithium hydroxide with respect to lithium nitrate (i.e., (Lithium Hydroxide)/(Lithium Nitrate)).

However, in a case where manganese oxide is reacted within a mixed molten salt of lithium hydroxide and lithium nitrate, it was understood that the resulting oxidizing condition is so weak that they have not reacted one another fully at all.

In view of such a problematic issue, the present invention aims at providing a novel production process in which fine-particle-shaped lithium-manganese-based oxide, which includes tetravalent manganese (Mn) element and whose crystal structure belongs to a layered rock-salt structure, is obtainable as a major product. Moreover, it aims at providing a positive-electrode active material including a composite oxide that is obtainable by means of this novel production process, and a secondary battery using the same.

### Means for Solving the Assignment

The present inventors found out that it is possible to produce composite oxides, which are fine and are of high crystallinity, by carrying out a reaction within a lithium-hydroxide molten salt by means of a molten-salt method, even without including any oxidative LiNO₃ or Li₂O₂, upon mainly producing lithium-manganese-based oxides, like Li₂MnO₃, which include tetravalent Mn alone, by means of the molten-salt method.

Specifically, a production process for composite oxide according to the present invention is characterized in that:

it is a production process for composite oxide, production process whose a major product is a lithium-manganese-based oxide that includes at least the following: a lithium (Li) element; and a tetravalent manganese (Mn) element, and lithium-manganese-based oxide whose crystal structure belongs to a layered rock-salt structure;

said composite oxide is obtained via the following:

a molten reaction step of reacting at least the following one another: a metal-containing raw material; and a molten-salt raw material at a melting point of the molten-salt raw material or more,

the metal-containing raw material including one or more kinds of metallic elements in which Mn is essential,

the molten-salt raw material including lithium hydroxide but not including any other compound virtually, and the molten-salt raw material including Li in an amount that exceeds a theoretical composition of Li being included in said composite oxide to be targeted; and

a recovery step of recovering said composite oxide being generated at said molten reaction step.

Note that it has been known in general that the higher the crystallinity is, namely, the more each of the particles is single-crystalline substantially, the more intense and the sharper diffraction peaks can be seen in a diffraction pattern that is obtainable by means of an X-ray diffraction (or XRD) measurement. Moreover, it is considered that, in Li₂MnO₃ with a layered rock-salt structure, “the crystallinity is high” in a case where the diffraction peak, which should be seen at around a diffraction angle: 2θ=63 degrees as a result of an XRD measurement employing the CuKα ray, is separated into two elements. Therefore, in the present description as well, when evaluating the crystallinity of composite oxides being obtainable by means of the production process for composite oxide according to the present invention, the composite oxides are regarded that “the crystallinity is high” in a case where the diffraction peak, which should be seen at around 2θ=63 degrees as a result of an XRD measurement for the composite oxides that employs the CuKα ray.

In the production process for composite oxide according to the present invention, a “metal-containing raw material,” which includes at least one kind of metallic elements in which Mn is essential, and a “molten-salt raw material,” which comprises lithium hydroxide alone virtually and includes Li excessively, are reacted one another. In order to synthesis composite oxides that include Li and tetravalent Mn at least while inhibiting Mn whose valence number is less than tetravalence from being inadvertently mingled into the resulting products, it is necessary that they can be in such highly oxidizing conditions that their reaction activities are high. It is believed that such a state can be brought about by means of basic molten salt and high reaction temperature. Since a molten salt of lithium hydroxide is highly basic, the resulting hydroxide ions are decomposed into oxygen ions and water in the molten salt of lithium hydroxide, and then the resultant water is evaporated from the high-temperature molten salt. As a result, a highly basic concentration and a dehydrating or dewatering environment can be obtained, and thereby a highly oxidizing condition that is suitable for the synthesis of desired composite oxide is formed.

Note that it is not necessarily advisable that the resulting molten salt can simply be basic; however, it is believed that, since the resultant molten salt is a molten salt of lithium hydroxide, lithium-manganese-based oxides, which include Li and tetravalent Mn and which belong to a layered rock-salt structure, are formed as a major product. For example, at paragraph “0024” in Patent Literature No. 3, it is set forth that the generation of Li₂MnO₃ including tetravalent Mn is inhibited due to the presence of potassium hydroxide that exists within the resulting molten salt in large excess. That is, it is important in what a type the resultant molten salt falls, namely, composite oxides at which the present invention aims are not necessarily obtainable only because the resulting molten salt is basic. Note that, in a molten salt comprising lithium hydroxide alone, not only the basicity of the molten salt is high but also the Li concentration becomes higher in the molten salt, compared with a case where a molten salt of salts other than lithium is used or a molten salt in which hydroxides are mixed one another is used. It is believed that a molten salt with a higher Li concentration can be suitable for the formation of layered rock-salt structure.

In accordance with the production process for composite oxide according to the present invention, composite oxides, whose major product is a lithium-manganese-based oxide that includes Li and tetravalent Mn at least and whose crystal structure belongs to a layered rock-salt structure, are obtainable as set forth above. In a case where a lithium-manganese-based oxide has a layered rock-salt structure, an average oxidation number of Mn is tetravalent fundamentally. However, due to the presence of Mn whose valance number falls short of being tetravalent, a valance number of from 3.8 to 4 is permissible as for an average oxidation number of Mn in the entirety of an obtainable composite oxide.

In addition, fine-particle-shaped composite oxides are obtainable by means of raising the metal-containing raw material and molten-salt raw material to a high temperature that is the melting point of lithium hydroxide or more and then reacting the metal-containing raw material within the resulting molten salt. This is because alkaline fusion occurs within the resultant molten salt so that the respective raw materials are mixed with each other uniformly. Moreover, composite oxides, whose primary particles are on the order of nanometers, are obtainable, because reacting the raw materials within a molten salt, which comprises lithium hydroxide alone virtually, inhibits them from undergoing granular growths even when the reaction temperature is high temperatures. Note that, as having been described already, relatively large composite oxides with 1 μm approximately are obtainable even by means of a molten-salt method in a case where manganese nitrate is reacted at 650° C. or more within a lithium-chloride molten salt as being set forth in Example No. 3 according to Patent Literature No. 2.

It is also advisable to carry out a precursor synthesis step, in which an aqueous solution including at least two kinds of metallic elements is alkalified in order to obtain precipitates, before the molten reaction step in the production process for composite oxide according to the present invention, and then to employ the resulting precipitates as at least apart of the metal-containing raw material at the molten reaction step. Composite oxides with a layered rock-salt structure, composite oxides which include, together with Li, one or more kinds of metallic elements as well as Mn, are obtainable in high purity by using the precipitates as a precursor.

Composite oxides, which are obtainable by means of the production process for composite oxide according to the present invention, can be employed as a positive-electrode active material for lithium-ion secondary battery, and the like. In other words, it is also possible to grasp the present invention as a positive-electrode active material that is characterized in including a composite oxide that is obtained by means of the production process for composite oxide according to the present invention, or furthermore as a secondary battery that uses this positive-electrode active material.

Moreover, a composite oxide, which is obtainable by means of the production process for composite oxide according to the present invention, has a lithium-manganese-based oxide as a basic composition, lithium-manganese-based oxide which is expressed by a compositional formula: xLi₂M¹O₃.(1−x) LiM²O₂ (where “M¹” is one or more kinds of metallic elements in which tetravalent Mn is essential; “M²” is one or more kinds of metallic elements; 0≦“x”≦1; and Li may even be substituted by hydrogen in a part thereof), or by another compositional formula: Li_{1.33-y}M¹_{0.67-z}M²_{y+z}O₂ (where “M¹” is one or more kinds of metallic elements in which tetravalent Mn is essential; “M²” is one or more kinds of metallic elements; 0≦“y”≦0.33; 0≦“Z”≦0.67; and Li may even be substituted by hydrogen in a part thereof), for instance. Note that it is needless to say that composite oxides, whose compositions have deviated slightly from the aforementioned compositional formulas due to the deficiency in Li, M¹, M² or O that occurs inevitably, are also included herein. In a case where a lithium-manganese-based oxide has a layered rock-salt structure, the average oxidation number of Mn is tetravalent fundamentally. However, as described above, a valance number of from 3.8 to 4 is permissible as for an average oxidation number of Mn in the entirety of an obtainable composite oxide, due to the presence of Mn with a valance number of less than tetravalence that results from the compositions being deviated from the above-mentioned basic compositions.

### Effect of the Invention

In accordance with the present invention, composite oxides are obtainable in a fine particulate shape, respectively, composite oxides in which a lithium-manganese-based oxide including lithium and tetravalent manganese and belonging to a layered rock-salt structure makes a major product.

### BRIEF DESCRIPTION OF THE DRAWINGS

FIG. 1 illustrates results of an X-ray diffraction measurement for a composite oxide (e.g., Li₂MnO₃) that was produced by means of a production process for composite oxide according to the present invention;

FIG. 2 illustrates results of an X-ray diffraction measurement for a composite oxide (e.g., 0.5(Li₂MnO₃).0.5 (LiCo_{1/3}Ni_{1/3}Mn_{1/3}O₂)) that was produced by means of a production process for composite oxide according to the present invention;

FIG. 3 illustrates results of an X-ray diffraction measurement for composite oxides that were produced by means of conventional processes;

FIG. 4 is a graph that illustrates charging/discharging characteristics of a lithium secondary battery in which a composite oxide (e.g., 0.5(Li₂MnO₃).0.5(LiCo_{1/3}Ni_{1/3}Mn_{1/3}O₂)) being produced by means of a production process for composite oxide according to the present invention was used as the positive-electrode active material;

FIG. 5 is a graph that illustrates charging/discharging characteristics of a lithium secondary battery in which a composite oxide (e.g., LiCo_{1/3}Ni_{1/3}Mn_{1/3}O₂) being produced by means of a production process for composite oxide according to the present invention was used as the positive-electrode active material;

FIG. 6 is a graph that illustrates cyclabilities of lithium secondary batteries in which composite oxides being produced by means of a production process for composite oxide according to the present invention were used as the positive-electrode active material, respectively; and

FIG. 7 is a graph that illustrates cyclabilities of lithium secondary batteries in which composite oxides being produced by means of a production process for composite oxide according to reference examples were used as the positive-electrode active material, respectively.

### MODES FOR CARRYING OUT THE INVENTION

Hereinafter, explanations will be made on some of the modes for performing the production process for composite oxide, positive-electrode active material and secondary battery according to the present invention. Note that, unless otherwise specified, ranges of numeric values, namely, “from ‘a’ to ‘b’” being set forth in the present description, involve the lower limit, “a,” and the upper limit, “b,” in those ranges. And, the other ranges of numeric values are composable by arbitrarily combining not only any two of these upper-limit values and lower-limit values but also any two of those involving the numeric values that are listed in specific examples.

### Composite Oxide

Hereinafter, the respective steps of a production process for composite oxide according to the present invention will be explained. The production process for composite oxide according to the present invention is a production process for composite oxide, production process whose a major product is a lithium-manganese-based oxide that includes at least the following: Li; and tetravalent Mn, and lithium-manganese-based oxide whose crystal structure belongs to a layered rock-salt structure. The production process includes a molten reaction step, and a recovery step mainly. The production process can further include a pre cursor synthesis step and/or a heat-calcination treatment step, and so on, if needed.

First of all, it is allowable to carry out a raw-material preparation step in which a metal-containing raw material and a molten-salt raw material are made ready. In the raw-material preparation step, it is permissible to mix the metal-containing raw material and the molten-salt raw material with each other. On this occasion, it is allowable to mix a powder-shaped metal-containing raw material, which is obtainable by pulverizing and so forth a simple-substance metal or metallic compound and the like, with a molten-salt raw material, which includes a powder of lithium hydroxide, one another in order to obtain a raw-material mixture. It is permissible that the metal-containing raw material can include one or more kinds of metallic compounds in which Mn is essential. The molten-salt raw material includes lithium hydroxide mainly.

As for the metal-containing raw material, it is allowable to use, as a raw material for supplying tetravalent Mn, one or more kinds of metallic compounds (or first metallic compounds) that are selected from the group consisting oxides, hydroxides and other metallic salts that include one or more kinds of metallic elements in which Mn is essential. It is preferable that one of these metallic compounds can be included in the metal-containing raw material essentially. To be concrete, the following can be given: manganese dioxide (MnO₂); dimanganese trioxide (Mn₂O₃); manganese monoxide (MnO); trimanganesetetraoxide (Mn₃O₄); manganese hydroxide (Mn(OH)₂); manganese oxyhydroxide (MnOOH); or metallic compounds in which a part of Mn in these compounds is substituted by Cr, Fe, Co, Ni, Al or Mg, and the like. It is permissible to use one kind or two or more kinds of these as a first metallic compound, respectively. Among them, MnO₂ is preferable because not only it can be procured easily but also those with comparatively high purities are likely to be procured. Here, Mn in the metallic compounds does not necessarily need to be tetravalent, but it is even permissible that it can be Mn with a valence number of 4 or less. This is due to the fact that even divalent or trivalent Mn turns into being tetravalent one because reactions proceed under highly oxidizing conditions. This holds true similarly for the metallic elements that substitute for Mn, too.

In accordance with the production process according to the present invention, it is also possible to produce composite oxides including a metallic element in addition to Li and tetravalent Mn, like composite oxides in which the other metallic elements, preferably transition metal elements, substitute for tetravalent Mn. If such is the case, it is allowable to further employ a second metallic compound including one or more kinds of metallic elements other than Mn, in addition to the aforementioned metallic compounds including one or more kinds of metallic elements in which Mn is essential. As for specific examples of the second metallic compounds, the following can be given: cobalt oxide (CoO, or Co₃O₄); cobalt nitrate (Co(NO₃)₂.6H₂O); cobalt hydroxide (Co(OH)₂); nickel oxide (NiO); nickel nitrate (Ni(NO₃)₂.6H₂O); nickel sulfate (NiSO₄.6H₂O); aluminum hydroxide (Al(OH)₃); aluminum nitrate (Al(NO₃)₃.9H₂O); copper oxide (CuO); copper nitrate (Cu(NO₃)₂.3H₂O); and calcium hydroxide (Ca(OH)₂). It is permissible to use one kind or two or more kinds of these as the second metallic compound.

Moreover, it is allowable to preliminarily synthesize in advance the metal-containing raw material that includes two or more kinds of metallic elements (which can possibly include Mn, too), in other words, an essential metallic compound and/or a second metallic compound, as a precursor that includes those raw materials. That is, before the molten reaction step, it is permissible to carry out a precursor synthesis step in which an aqueous solution including at least two kinds of metallic elements is alkalified in order to obtain precipitates. At the molten reaction step, it is feasible to employ the metal-containing raw material that includes the thus obtained precipitates. As for an aqueous solution, water-soluble inorganic salts, specifically, nitrates, sulfates or chlorides of the metallic elements, and the like, are dissolved in water. When the result ing aqueous solution is alkalified with alkali metal hydroxide or ammonia water, and so forth, a precursor can be generated as precipitates.

Although the molten-salt raw material makes a supply source for Li, it includes Li in an amount that exceeds a theoretical composition of Li being included in composite oxides to be produced. Although a molten salt of lithium hydroxide is used mainly in the production process for composite oxide according to the present invention, the lithium hydroxide not only plays a role of a supply source for Li, but also plays a role of adjusting an oxidizing power of the resulting molten salt. Although it is allowable that a ratio, a theoretical composition of Li to be included in a targeted composite oxide with respect to Li being included in the molten-salt raw material (i.e., (Li in Composite Oxide)/(Li in Molten-salt Raw Material)), can be less than 1 by molar ratio; it is preferable to be from 0.02 to 0.7; or it is more preferable to be from 0.03 to 0.5, or furthermore from 0.04 to 0.25. Being less than 0.02 is not desirable in the prospect of production efficiency, because an amount of generating composite oxides becomes less with respect to an amount of the employed molten-salt raw material. Moreover, being 0.7 or more is not desirable, because an amount of the resulting molten salt that disperses the metal-containing raw material runs short, so that the resultant composite oxides might possibly undergo agglomeration or granular growth within the molten salt.

Since the molten-salt raw material does not include any compound other than lithium hydroxide, it is desirable that it can comprise lithium hydroxide alone virtually. However, since lithium hydroxide has such a quality that it absorbs carbon dioxide in atmospheric air to turn into lithium carbonate, there might possibly arise such a case that it includes a trace amount of lithium carbonate as an impurity. When prescribing this daringly, it is preferable that the molten-salt raw material can include lithium hydroxide in an amount of 95% by mol or more, or 97% by mol or more, or furthermore 99% by mol or more, when the entire molten-salt raw material is takes as 100% by mol. It is permissible that lithium hydroxide can be employed independently as the molten-salt raw material, and that it does not include any of the following: oxides, such as lithium peroxide; hydroxides, such as potassium hydroxide and sodium hydroxide; and metallic salts, such as lithium nitrate. In particular, since the molten salt of lithium hydroxide has the highest basicity among lithium compounds, it exhibits an oxidizing power that is suitable for the synthesis of targeted composite oxides by employing lithium hydroxide independently. Moreover, even when a temperature of the resulting molten salt is high temperatures, it becomes feasible to synthesize composite-oxide particles with smaller particle diameters by employing lithium hydroxide independently.

Note that, for lithium hydroxide, it is also advisable to use its anhydride as well as to use its hydrates. That is, as for an employable lithium hydroxide, LiOH (i.e., anhydride), LiOH.H₂O (i.e., hydrate), and the like, can be given.

Note that it is desirable that lithium hydroxide to be employed can be in a dehydrated or dewatered state. Hence, it is also advisable to carry out, before the molten reaction step, a drying step in which at least lithium hydroxide being included in the metal-containing raw material and molten-salt raw material is dried. However, it is even feasible to abbreviate the drying step in a case where no highly-hygroscopic metallic compounds are employed as the metal-containing raw material, or in a case where no hydrates of lithium hydroxide are employed as the molten-salt raw material, and the like.

It is advisable that the drying can be done by vacuum drying at from 80 to 150° C. for from 2 to 24 hours when a vacuum drier is used. Water, which exists within a molten salt comprising the molten-salt raw material that includes lithium hydroxide, has a pH that is heightened very much. When the molten reaction step is carried out in the presence of water with a high pH, since that water makes contact with a crucible, there is such a possibility that the crucible's components might elute into the resulting molten salt, although in a trace amount, depending on the types of crucibles. Since water contents in the raw materials are removed in the drying step, this leads to inhibiting the crucible's components from eluting. Note that, in a case where anhydrous lithium hydroxide or lithium hydroxide monohydrate is dehydrated or dewatered in advance to employ, a similar advantageous effect is obtainable even when the drying step is abbreviated. Moreover, it is possible to prevent water from boiling to dissipate the resultant molten salt at the molten reaction step by means of removing the water content from lithium hydroxide at least at the drying step.

The molten reaction step is a step in which the molten-salt raw material is melted to react it with the metal-containing raw material. The reaction temperature is a temperature of the resulting molten salt at the molten reaction step, and it is advisable that it can be a melting point or more of the molten-salt raw material. However, at less than 500° C., since the resultant molten salt's reaction activity is insufficient so that it is difficult to produce desired composite oxides including tetravalent Mn with good selectivity, it is desirable to react them at 500° C. or more. Moreover, when the reaction temperature is 550° C. or more, composite oxides, which are of high crystallinity, are obtainable. An upper limit of the reaction temperature can be less than the decomposition temperature of lithium hydroxide, and it is desirable that it can be 900° C. or less, or furthermore 850° C. or less. When employing manganese dioxide as a metallic compound that supplies Mn, it is desirable that the reaction temperature can be from 500 to 700° C., or furthermore from 550 to 650° C. The reaction temperature being too high is not desirable, because the decomposition reaction of the resulting molten salt occurs. When the metal-containing raw material and molten-salt raw material are retained at such a temperature for 30 minutes or more, more desirably for from 1 to 6 hours, they react one another sufficiently.

Moreover, when the molten reaction step is carried out in an oxygen-containing atmosphere, for example, in air or in a gaseous atmosphere including oxygen gas and/or ozone gas, composite oxides including tetravalent Mn are likely to be obtained in a single phase. When being an atmosphere containing oxygen gas, it is advisable to set an oxygen-gas concentration at from 20 to 100% by volume, or furthermore from 50 to 100% by volume. Note that the higher the oxygen concentration is set the smaller the particle diameters of composite oxides to be synthesized tend to become.

On this occasion, it is desirable to employ a crucible, such as those made of gold from which the components are less likely to elute into the resulting molten salt, for the reaction, because the basicity of the molten salt is high and the reaction temperature is also high. For example, employing a nickel crucible is not desirable, because Ni elutes into the resultant molten salt, so that impurities (e.g., NiO, and the like) other than composite oxide are generated.

The recovery step is a step of recovering a composite oxide that has been generated at the molten reaction step. It is also advisable for the recovery step to further include a cooling step of cooling the molten-salt raw material that has been melted at the molten reaction step (namely, the resulting molten salt).

There are not any limitations especially on the recovery method for composite oxides having been generated; however, since composite oxides, which have been generated at the molten reaction step, are insoluble in water, the resulting molten salt is cooled sufficiently to solidify in order to turn them into solids, then the resultant solids are dissolved in water, and thereby the composite oxides are obtainable as insoluble substances. Thus, it is advisable to take out the resulting composite oxides by drying filtered substances that have been obtained by filtering the resultant aqueous solution.

At the cooling step, the resulting high-temperature molten salt, which has completed the reaction, is cooled gradually. To be concrete, it is also allowable to furnace cool it by leaving it inside a heating furnace, or it is even permissible to take it out from the heating furnace and then air cool it at room temperature. When prescribing this concretely, the cooling can be done at a rate of from 2° C./minute or more to 50° C./minutes or less, or furthermore from 3 to 25° C./minute, until the resulting molten salt's temperature becomes 450° C. or less (namely, until the resultant molten salt solidifies), because composite oxides, which are of high crystallinity, are obtainable, and especially because that is advantageous for the synthesis of composite oxides that have a layered rock-salt structure, respectively.

Moreover, after the recovery step, it is also advisable to carry out a proton substitution step in which hydrogen (H) substitutes for a part of Li in the resulting composite oxides. In the proton substitution step, a part of Li in the resultant post-recovery-step composite oxides can be replaced readily by H by means of contacting the composite oxides with a solvent such as a diluted acid.

Moreover, after the recovery step (or the proton substitution step), it is even advisable to carry out a heat-calcination treatment step in which the resulting composite oxides are heated in an oxygen-containing atmosphere. Residual stresses, which exist in the resultant composite oxides, are removed by means of carrying out calcination. Moreover, composite oxides are obtainable, composite oxides in which impurities have been reduced, because carrying out calcination reduces the impurities that have not been removed completely at the recovery step to turn into films, for instance, and which then reside on the surface of the resulting composite oxides. It is believed that, in such impurities, one or more kinds of lithium compounds, which are selected from lithium hydroxide serving as the molten-salt raw material, or lithium salts such as Li₂CO₃, and the like, make the major component. Consequently, in a case where an amount of Li that is contained in the resultant composite oxides is less than that in the theoretical composition (i.e., Li deficiency), the superficial portion of the composite oxides is reacted with the lithium compounds by means of the heat of calcination, so that not only the Li deficiency in the resulting composite oxides can be reduced but also the lithium compounds can be decomposed. That is, as a result of calcination, composite oxides are obtainable, composite oxides from which the residual stresses have been removed, and in which the superficial impurities and Li deficiency have been reduced.

The calcination can be carried out in an oxygen-containing atmosphere. It is allowable to carry out the heat-calcination treatment step in an oxygen-containing atmosphere, for example, in air or in a gaseous atmosphere including oxygen gas and/or ozone gas. When being an atmosphere containing oxygen gas, it is permissible to set an oxygen-gas concentration at from 20 to 100% by volume, or furthermore from 50 to 100% by volume. It is desirable that a calcination temperature can be 300° C. or more, or furthermore from 350 to 500° C., and it is desirable to retain the resulting composite oxides at such a temperature for 20 minutes or more, or furthermore for from 0.5 to 2 hours.

The composite oxides, which have been obtained by means of the production process according to the present invention that has been detailed so far, can preferably comprise single-crystalline primary particles. It is possible to ascertain that the primary particles are single crystalline by means of high-resolution image by TEM. It is preferable that that the c-axis-direction particle diameters of the primary particles in the composite oxides can be 200 nm or less, or furthermore from 20 to 100 nm, according to the Scherrer equation. Note that a half-value width is taken as a value that is measured at the position of an intensity that is calculated by Iₘₐₓ/2 when the maximum intensity of (001) in Li₂MnO₃, which can be seen in the vicinity of 18.5-degree diffraction angle (2θ, CuKα ray used), is labeled the “Iₘₐₓ.” As described earlier, the smaller the primary particle diameters are the more likely it is that they can be activated; however, being too small is not preferable, because their crystal structures become likely to collapse due to charging and discharging so that the resulting battery characteristics might possibly decline.

It is possible for the production process according to the present invention to produce lithium-manganese-based oxides, which include tetravalent Mn, as a major product, and accordingly their structures are a layered rock-salt structure, especially an α-NaFeO₂ type layered rock-salt structure, respectively. It is possible to ascertain that a composite oxide is made up of a layered rock-salt structure chiefly by means of X-ray diffraction (or XRD), electron-beam diffraction, and the like. Moreover, a layered structure is observable by the high-resolution image using a high-resolution transmission electron microscope (or TEM).

When expressing obtainable composite oxides by a compositional formula, the compositional formula can be xLi₂M¹O₃.(1−x)LiM²O₂ (where “x” satisfies 0≦“x”≦1; “M¹” is one or more kinds of metallic elements in which tetravalent Mn is essential; and “M²” is one or more kinds of metallic elements). Note that it is also allowable that Li can be substituted by H in an amount of 60% or less, or furthermore 45% or less, by atomic ratio. Moreover, although it is preferable that “M¹” can be tetravalent Mn inmost part thereof, it is even permissible that it can be substituted by the other metallic elements in an amount of less than 50%, or furthermore less than 80%. As for metallic elements other than tetravalent Mn that constitute “M¹” and “M²,” it is preferable that they can be selected from the group consisting of Ni, Al, Co, Fe, Mg, and Ti, from a viewpoint of chargeable/rechargeable capacity in a case where they are made into electrode materials. Note that, in a case where Ni is included in “M¹” or “M²,” the generation of by-products (e.g., NiO), which are difficult to remove, can be inhibited by means of adopting the production process in which a precursor is used as described earlier. Note also that it is needless to say that composite oxides, whose compositions have deviated slightly from the aforementioned compositional formula due to the deficiency in Li, “M¹,” “M²” or O that occurs inevitably, are also included herein. Therefore, a valance number of from 3.8 to 4 is permissible for an average oxidation number of Mn that is included in “M¹,” and for an average number of Mn that is included in “M².”

To be concrete, the following can be given: Li₂MnO₃, LiNi_{1/3}Co_{1/3}Mn_{1/3}O₂, and LiNi_{0.5}Mn_{0.5}O₂; or solid solutions that include two or more kinds of these. Moreover, it is also allowable that they can include Li₂M¹O₃ indispensably and can further include LiCoO₂, LiNiO₂, or LiFeO₂, and the like. It is even permissible that a part of Mn, Ni, Co or Fe can be substituted by the other metallic elements. It is also allowable that, as for the entirety of obtainable composite oxide, the composite oxides can be made up of the exemplified oxides as a basic composition, respectively. It is even permissible that their compositions can deviate slightly from the aforementioned compositional formulas due to the deficiency in the metallic elements or oxygen that occurs inevitably.

### Secondary Battery

It is possible to use the composite oxides, which have been obtained by means of the production process for composite oxide according to the present invention, as a positive-electrode active material, for instance, for lithium-ion secondary battery, and the like, respectively. Hereinafter, explanations will be made on a secondary battery using a positive-electrode active material that includes one of the aforementioned composite oxides. A secondary battery is mainly equipped with a positive electrode, a negative electrode, and a non-aqueous electrolyte. Moreover, in the same manner as common secondary batteries, it is further equipped with a separator, which is held between the positive electrode and the negative electrode.

The positive electrode includes a positive-electrode active material into which lithium ions can be inserted and from which they can be eliminated, and a binding agent that binds the positive-electrode active material together. It is also allowable that it can further include a conductive additive. The positive-electrode active material includes one of the above-mentioned composite oxides independently. Alternatively, it is even permissible that the positive-electrode active material can further include one or more kinds of the other positive-electrode active materials being selected from the group consisting of LiCoO₂, LiNi_{1/3} CO_{1/3}Mn_{1/3}O₂, LiMn₂O₄, S, and the like, which have been used for common secondary batteries, along with one of the above-mentioned composite oxides.

Moreover, there are not any limitations especially on the binding agent and conductive additive, and so they can be those which are employable in common secondary batteries. The conductive additive is one for securing the electric conductivity of electrode, and it is possible to use for the conductive additive one kind of carbon-substance powders, such as carbon blacks, acetylene blacks and graphite, for instance; or those in which two or more kinds of them have been mixed with each other. The binding agent is one which accomplishes a role of fastening and holding up the positive-electrode active material and the conductive additive together, and it is possible to use for the binding agent the following: fluorine-containing resins, such as polyvinylidene fluoride, polytetrafluoroethylene and fluororubbers; or thermoplastic resins, such as polypropylene and polyethylene, for instance.

The negative electrode to be faced to the positive electrode can be formed by making metallic lithium, namely, a negative-electrode active material, into a sheet shape. Alternatively, it can be formed by press bonding the one, which has been made into a sheet shape, onto a current-collector net, such as nickel or stainless steel. Instead of metallic lithium, it is possible to use lithium alloys or lithium compounds as well. Moreover, in the same manner as the positive electrode, it is also allowable to employ a negative electrode comprising a negative-electrode active material, which can absorb lithium ions and from which they can be desorbed, and a binding agent. As for a negative-electrode active material, it is possible to use the following: natural graphite; artificial graphite; organic-compound calcined bodies, such as phenolic resins; and powders of carbonaceous substances, such as cokes, for instance. As for a binding agent, it is possible to use fluorine-containing resins, thermoplastic resins, and the like, in the same manner as the positive electrode.

It is common that the positive electrode and negative electrode are made by adhering an active-material layer, which is made by binding at least a positive-electrode active material or negative-electrode active material together with a binding agent, onto a current collector. Consequently, the positive electrode and negative electrode can be formed as follows: a composition for forming electrode mixture-material layer, which includes an active material and a binding agent as well as a conductive additive, if needed, is prepared; the resulting composition is applied onto the surface of a current collector after an appropriate solvent has been further added to the resultant composition to make it pasty, and is then dried thereon; and the composition is compressed in order to enhance the resulting electrode density, if needed.

For the current collector, it is possible to use meshes being made of metal, or metallic foils. As for a current collector, porous or nonporous electrically conductive substrates can be given, porous or nonporous electrically conductive substrates which comprise: metallic materials, such as stainless steels, titanium, nickel, aluminum and copper; or electrically conductive resins. As for a porous electrically conductive substrate, the following can be given: meshed bodies, netted bodies, punched sheets, lathed bodies, porous bodies, foamed bodies, and formed bodies of fibrous assemblies like nonwoven fabrics, for instance. As for a nonporous electrically conductive substrate, the following can be given: foils, sheets, and films, for instance. As for an applying method of the composition for forming electrode mixture-material layer, it is advisable to use a method, such as doctor blade or bar coater, which has been heretofore known publicly.

As for a solvent for viscosity adjustment, the following are employable: N-methyl-2-pyrrolidone (or NMP), methanol, methyl isobutyl ketone (or MIBK), and the like.

As for an electrolyte, it is possible to use organic-solvent-based electrolytic solutions, in which an electrolyte has been dissolved in an organic solvent, or polymer electrolytes, in which an electrolytic solution has been retained in a polymer, and the like. Although the organic solvent, which is included in that electrolytic solution or polymer electrolyte, is not at all one which is limited especially, it is preferable that it can include a chain ester (or a linear ester) from the perspective of load characteristic. As for such a chain ester, the following organic solvents can be given: chain-like carbonates, which are represented by dimethyl carbonate, diethyl carbonate and ethyl methyl carbonate; ethyl acetate; and methyl propionate, for instance. It is also advisable to use one of these chain or linear esters independently, or to mix two or more kinds of them to use. In particular, in order for the improvement in low-temperature characteristic, it is preferable that one of the aforementioned chain esters can account for 50% by volume or more in the entire organic solvent; especially, it is preferable that the one of the chain esters can account for 65% by volume or more in the entire organic solvent.

However, as for an organic solvent, rather than constituting it of one of the aforementioned chain esters alone, it is preferable to mix an ester whose permittivity is high (e.g., whose permittivity is 30 or more) with one of the aforementioned chain esters to use in order to intend the upgrade in discharged capacity. As for a specific example of such an ester, the following can be given: cyclic carbonates, which are represented by ethylene carbonate, propylene carbonate, butylene carbonate and vinylene carbonate; γ-butyrolactone; or ethylene glycol sulfite, for instance. In particular, cyclically-structured esters, such as ethylene carbonate and propylene carbonate, are preferable. It is preferable that such an ester whose permittivity is high can be included in an amount of 10% by volume or more in the entire organic solvent, especially 20% by volume or more therein, from the perspective of discharged capacity. Moreover, from the perspective of load characteristic, 40% by volume or less is more preferable, and 30% by volume or less is much more preferable.

As for an electrolyte to be dissolved in the organic solvent, one of the following can be used independently, or two or more kinds of them can be mixed to use: LiClO₄, LiPF₆, LiBF₄, LiAsF₆, LiSbF₆, LiCF₃SO₃, LiC₄F₉SO₃, LiCF₃CO₂, Li₂C₂F₄(SO₃)₂, LiN(CF₃SO₂)₂, LiC(CF₃SO₂)₃, and LiCₙF₂ₙ₊₁SO₃ (where “n”≧2), and the like, for instance. Among them, LiPF₆ or LiC₄F₉SO₃, and so forth, from which favorable charging/discharging characteristics are obtainable, can be used preferably.

Although a concentration of the electrolyte in the electrolytic solution is not at all one which is limited especially, it can preferably be from 0.3 to 1.7 mol/dm³, especially from 0.4 to 1.5 mol/dm³ approximately.

Moreover, in order to upgrade the safety or storage characteristic of battery, it is also advisable to make a non-aqueous electrolytic solution contain an aromatic compound. As for an aromatic compound, benzenes having an alkyl group, such as cyclohexylbenzene and t-butylbenzene, biphenyls, or fluorobenzenes can be used preferably.

As for a separator, it is advisable to use those which have sufficient strength, and besides which can retain electrolytic solutions in a large amount. From such a viewpoint, it is possible to use the following, which have a thickness of from 5 to 50 μm, preferably: micro-porous films which are made of polypropylene, polyethylene or polyolefin, such as copolymers of propylene and ethylene; or nonwoven fabrics. In particular, in a case where such a thin separator as having from 5 to 20 μm in thickness is used, the characteristics of battery are likely to degrade during charging/discharging cycles or storage at high temperatures, and the safety declines as well. However, since a secondary battery, in which one of the above-mentioned composite oxides is used as the positive-electrode active material, is excellent in the stability and safety, it is possible to make the resulting batteries function stably even when such a thin separator is used.

A configuration of secondary batteries, which are constituted by means of the constituent elements as above, can be made into various sorts of those such as cylindrical types, laminated types and coin types. Even in a case where any one of the configurations is adopted, the separators are interposed between the positive electrodes and the negative electrodes to make electrode assemblies. And, these electrode assemblies are sealed hermetically in a battery case after connecting intervals from the resulting positive-electrode current-collector assemblies and negative-electrode current-collector assemblies up to the positive-electrode terminals and negative-electrode terminals, which lead to the outside, with leads and the like for collecting electricity, and then impregnating these electrode assemblies with the aforementioned electrolytic solution, and thereby a secondary battery completes.

In a case where secondary batteries are made use of, the positive-electrode active material is activated by carrying out charging in the first place. However, in a case where one of the above-mentioned composite oxides is used as a positive-electrode active material, lithium ions are released at the time of first-round charging, and simultaneously therewith oxygen generates. Consequently, it is desirable to carry out charging before sealing the battery case hermetically.

A secondary battery, in which one of the composite oxides being obtained by means of the production process according to the present invention as explained above is used, can be utilized suitably in the field of automobile in addition to the field of communication device or information-related device such as cellular phones and personal computers. For example, when vehicles have this secondary battery on-board, it is possible to employ the secondary battery as an electric power source for electric automobile.

So far, some of the embodiment modes of the production process for composite oxide, positive-electrode active material for non-aqueous-electrolyte secondary battery and non-aqueous-electrolyte secondary battery according to the present invention have been explained. However, the present invention is not one which is limited to the aforementioned embodiment modes. It is possible to execute the present invention in various modes, to which changes or modifications that one of ordinary skill in the art can carry out are made, within a range not departing from the gist.

### EXAMPLES

Hereinafter, the present invention will be explained in detail while giving specific examples of the production process for composite oxide, positive-electrode active material for non-aqueous-electrolyte secondary battery and non-aqueous-electrolyte secondary battery according to the present invention.

### Example No. 1-1

### Synthesis of Li₂MnO₃

0.20-mol (i.e., 8.4-gram) lithium hydroxide monohydrate, LiOH.H₂O which served as a molten-salt raw material, and 0.02-mol (i.e., 1.74-gram) manganese dioxide, MnO₂ which served as a metallic-compound raw material, were mixed one another, thereby preparing a raw-material mixture. On this occasion, let us assume that Mn in the manganese dioxide was supplied completely to the resulting Li₂MnO₃ because a targeted product was Li₂MnO₃, then, the ratio, namely, (Li in Targeted Product)/(Li in Molten-salt Raw Material), was 0.04 mol/0.2 mol=0.2.

The raw-material mixture was put in a crucible, and was then vacuum dried by a vacuum drier at 120° C. for 12 hours. Thereafter, the drier was returned back to the atmospheric pressure; the crucible, in which the raw-material mixture was held, was taken out and was then transferred into a 700° C. electric furnace immediately, and was further heated at 700° C. for 2 hours in a vacuum. On this occasion, the raw-material mixture was fused to turn into a molten salt, and thereby a black-colored product deposited.

Next, the crucible, in which the molten salt was held, was taken out from the electric furnace after cooling it to room temperature within the electric furnace. After the molten salt was cooled fully to solidify, the solidified molten salt was dissolved in water by immersing the molten salt as being held in the crucible into 200-mL ion-exchanged water and then stirring them therein. Since the black-colored product was insoluble in water, the water turned into a black-colored suspension liquid. When filtering the black-colored suspension liquid, a transparent filtrate was obtained, and a black-colored, solid filtered substance was obtained on the filter paper. The obtained filtered substance was further filtered while washing it fully with use of acetone. After vacuum drying the post-washing black-colored solid at 120° C. for 12 hours, it was pulverized using a mortar and pestle.

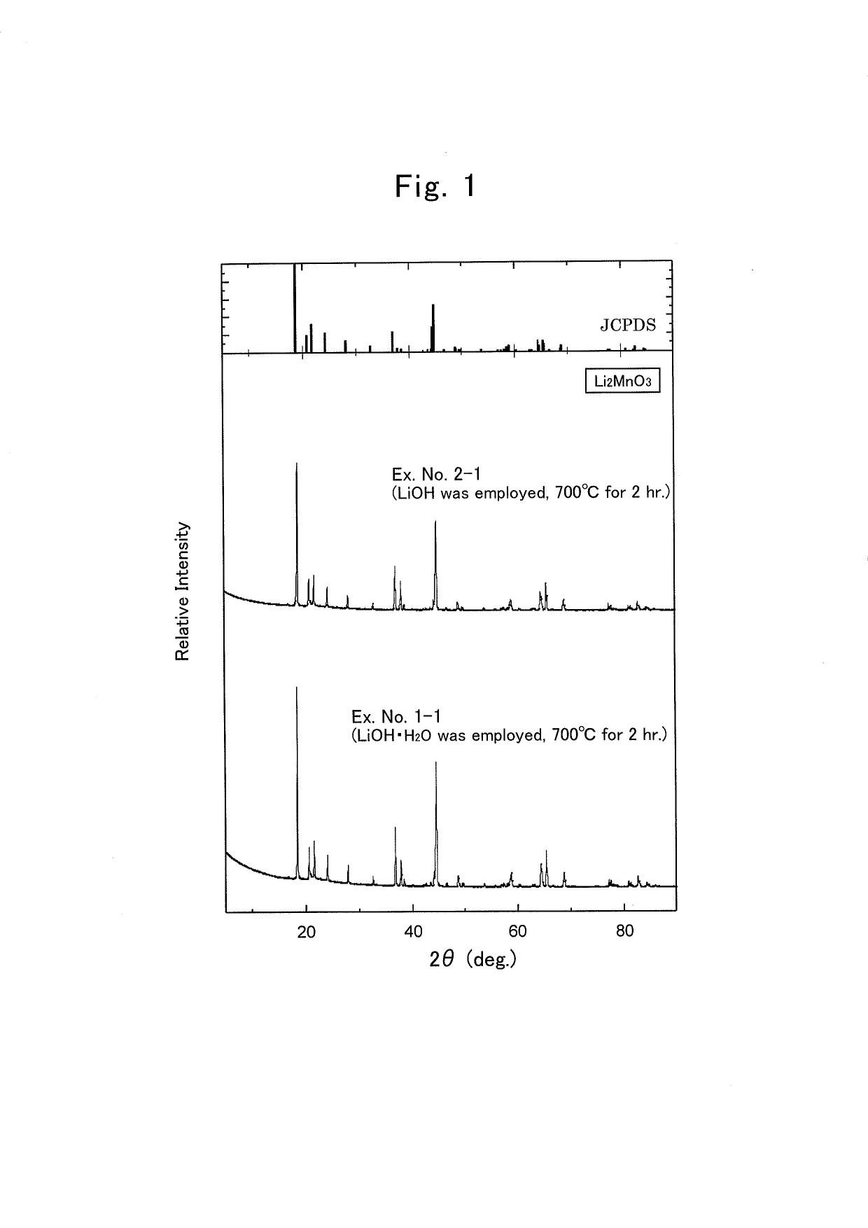

An X-ray diffraction (or XRD) measurement, in which the CuKα ray was used, was carried out for the obtained black-colored powder. The measurement result is shown in FIG. 1. According to the XRD, it was understood that the obtained compound had an α-NaFeO₂ type layered rock-salt structure. Moreover, according to an emission spectroscopic (e.g., ICP) analysis and an average valence analysis of Mn by means of oxidation-reduction titration, it was ascertained that an obtained composition was Li₂MnO₃.

Note that the evaluation on the valence of Mn was carried out as follows. A sample was taken in an amount of 0.05 g in an Erlenmeyer flask; a 1% sodium oxalate solution was added thereto in an amount of 40 mL accurately; H₂SO₄ was further added thereto in an amount of 50 mL; and then the sample was dissolved within a 90° C. water bath in a nitrogen-gas atmosphere. To the resulting mixture solution, 0.1N potassium permanganate was dropped to titrate it, and the titration was carried out until an end point at which the mixture solution changed the color to a faint rouge-like color (i.e., a titer, “V1”). Meanwhile, another 1% sodium oxalate solution was taken in an amount of 20 mL accurately in another flask, and another 0.1N potassium permanganate was dropped to titrate the resultant mixture solution in the same manner as aforementioned until the end point (i.e., another titer, “V2”). According to the following equation, an amount of oxalic acid, which was consumed when Mn with higher number of valence was reduced to Mn²⁺, was calculated as an oxygen amount (or active-oxygen amount) from the “V1” and “V2.”

(Active-oxygen Amount) (%)=[{(2×“V2”−“V1”)×0.00080}/(Amount of Sample)]×100

In the above-mentioned equation, the units of the “V1” and “V2” were milliliters (mL), and the units of the amount of sample were grams (g). And, an averaged valence of Mn was calculated from an Mn amount in the sample (e.g., a measured value by ICP analysis) and the resulting active-oxygen amount.

### Example No. 1-2

### Synthesis of Li₂MnO₃

0.20-mol lithium hydroxide monohydrate (i.e., 8.4-gram LiOH.H₂O), which served as a molten-salt raw material, and 0.010-mol manganese dioxide (i.e., 0.87-gram MnO₂), which served as a metallic-compound raw material, were mixed one another, thereby preparing a raw-material mixture. On this occasion, let us assume that Mn in the manganese dioxide was supplied completely to the resulting Li₂MnO₃ because a targeted product was Li₂MnO₃, then, the ratio, namely, (Li Amount in Targeted Product)/(Li Amount in Molten-salt Raw Material), was 0.020 mol/0.2 mol=0.1.

The raw-material mixture was put in a crucible, and was then vacuum dried at 120° C. for 12 hours in a vacuum-drying container. Thereafter, a drying machine was returned back to the atmospheric pressure; the crucible, in which the raw-material mixture was held, was taken out and was then transferred into a 700° C. electric furnace immediately, and was further heated within the 700° C. electric furnace for 1 hour. On this occasion, the raw-material mixture inside the crucible was fused to turn into a molten salt, and thereby a brown-colored product deposited.

Next, the crucible, in which the molten salt was held, was taken out from the electric furnace, and was then cooled at room temperature. After the molten salt was cooled fully to solidify, the solidified molten salt was dissolved in water by immersing the molten salt as being held in the crucible into 200-mL ion-exchanged water and then stirring them therein. Since the resulting product was insoluble in water, the water turned into a brown-colored suspension liquid. When filtering the brown-colored suspension liquid, a transparent filtrate was obtained, and a brown-colored, solid filtered substance was obtained on the filter paper.

The obtained filtered substance was further filtered while washing it fully with use of acetone. After vacuum drying the post-washing brown-colored solid at 120° C. for 12 hours, it was pulverized using a mortar and pestle, thereby obtaining a brown-colored powder.

The average valence analysis of Mn by means of ICP and oxidation-reduction titration was carried out for the obtained brown-colored powder. As a result, it was ascertained that its composition was Li₂MnO₃. As a result of carrying out the XRD measurement, in which the CuKα ray was used, for the obtained brown-colored powder, it was understood that the brown-colored power had an α-NaFeO₂ type layered rock-salt structure.

### Example No. 1-3

The brown-colored powder (or Li₂MnO₃), which was obtained in Example No. 1-2, was put in a crucible, and was then heated within a 700° C. electric furnace for 6 hours, thereby calcining the brown-colored powder.

### Example No. 2-1

### Synthesis of Li₂MnO₃

Except that, instead of the LiOH.H₂O, 0.20-mol (i.e., 4.79-gram) anhydrous lithium hydroxide, LiOH, was used as a molten-salt raw material, Li₂MnO₃ was synthesized in the same manner as Example No. 1-1.

The X-ray diffraction (or XRD) measurement, in which the CuKα ray was used, was carried out for the obtained black-colored powder. The measurement result is shown in FIG. 1. According to the XRD, it was understood that the obtained compound had an α-NaFeO₂ type layered rock-salt structure. Moreover, according to the average valence analysis of Mn by means of emission spectroscopic (e.g., ICP) analysis and oxidation-reduction titration, it was ascertained that an obtained composition was Li₂MnO₃.

### Example No. 2-2

### Synthesis of Li₂MnO₃

0.20-mol anhydrous lithium hydroxide (i.e., 4.79-gram LiOH), which served as a molten-salt raw material, and 0.010-mol manganese dioxide (i.e., 0.87-gram MnO₂), which served as a metallic-compound raw material, were mixed one another, thereby preparing a raw-material mixture. On this occasion, let us assume that Mn in the manganese dioxide was supplied completely to the resulting Li₂MnO₃ because a targeted product was Li₂MnO₃, then, the ratio, namely, (Li Amount in Targeted Product)/(Li Amount in Molten-salt Raw Material), was 0.020 mol/0.2 mol=0.1.

After putting the raw-material mixture as it was in a crucible without carrying out any vacuum drying, it was transferred into a 700° C. electric furnace and was then heated within the 700° C. electric furnace for 1 hour. In the present example, although no drying step was carried out, the molten salt did not dissipate at all within the furnace because the used lithium hydroxide was anhydrous.

Next, the crucible, in which the molten salt was held, was taken out from the electric furnace. From this and later on, a black-colored powder was obtained by means of the same procedure as that in Example No. 1-1.

The XRD measurement, in which the CuKα ray was used, was carried out for the obtained black-colored powder. According to the XRD, it was understood that the obtained compound had an α-NaFeO₂ type layered rock-salt structure. Moreover, according to the average valence analysis of Mn by means of ICP and oxidation-reduction titration, it was ascertained that an obtained composition was Li₂MnO₃.

### Example No. 3

### Synthesis of 0.5(Li₂MnO₃).0.5(LiCo_{1/3}Ni_{1/3}Mn_{1/3}O₂)

A mixed phase of Li₂MnO₃ and LiCo_{1/3} Ni_{1/3}Mn_{1/3}O₂ was synthesized by means of the following procedure.

0.30-mol (i.e., 12.6-gram) lithium hydroxide monohydrate, LiOH.H₂O, which served as a molten-salt raw material, was mixed with a 1.0-gram precursor, which served as a metallic-compound raw material, to prepare a raw-material mixture. Hereinafter, a synthesis procedure for the precursor will be explained.

0.268-mol (i.e., 76.93-gram) Mn(NO₃)₂.6H₂O, 0.064-mol (i.e., 18.63-gram) Co(NO₃)₂.6H₂O, and 0.064-mol (i.e., 18.61-gram) Ni(NO₃)₂.6H₂O were dissolved in 500-mL distilled water to make a metallic-salt-containing aqueous solution. While this aqueous solution was stirred within an ice bath using a stirrer, one in which 50-gram (i.e., 1.2-mol) LiOH.H₂O had been dissolved in 300-mL distilled water was dropped to the aqueous solution over a time period of 2 hours to alkalify it, thereby precipitating deposits of metallic compounds. While keeping this solution holding deposits therein at 5° C., aging was carried out for one day in an oxygen atmosphere. A precursor with Mn:Co:Ni=0.67:0.16:0.16 was obtained by means of filtering the obtained deposits and then washing them with use of distilled water.

Note that it was ascertained by means of the X-ray diffraction measurement that the obtained precursor comprised a mixed phase between Mn₃O₄, CO₃O₄ and NiO. Consequently, a content of transition metal oxides was 0.013 mol in 1 gram of this precursor. On this occasion, let us assume that the transition metals in the precursor were supplied completely to the resulting targeted product, then, the ratio, namely, (Li in Targeted Product)/(Li in Molten-salt Raw Material), was 0.0195 mol/0.3 mol=0.065.

The raw-material mixture was put in a crucible, and was then vacuum dried by a vacuum drier at 120° C. for 12 hours. Thereafter, the drier was returned back to the atmospheric pressure; the crucible, in which the raw-material mixture was held, was taken out and was then transferred immediately into an electric furnace, which had been heated to 500° C., and was further heated at 500° C. for 4 hours in air. On this occasion, the raw-material mixture was fused to turn into a molten salt, and thereby a black-colored product deposited.

Next, the crucible, in which the molten salt was held, was taken out from the electric furnace, and was then cooled at room temperature in air. After the molten salt was cooled fully to solidify, the solidified molten salt was dissolved in water by immersing the molten salt as being held in the crucible into 200-mL ion-exchanged water and then stirring them therein. Since the black-colored product was insoluble in water, the water turned into a black-colored suspension liquid. When filtering the black-colored suspension liquid, a transparent filtrate was obtained, and a black-colored, solid filtered substance was obtained on the filter paper. The obtained filtered substance was further filtered while washing it fully with use of ion-exchanged water. After vacuum drying the post-washing black-colored solid at 120° C. for 6 hours, it was pulverized using a mortar and pestle.

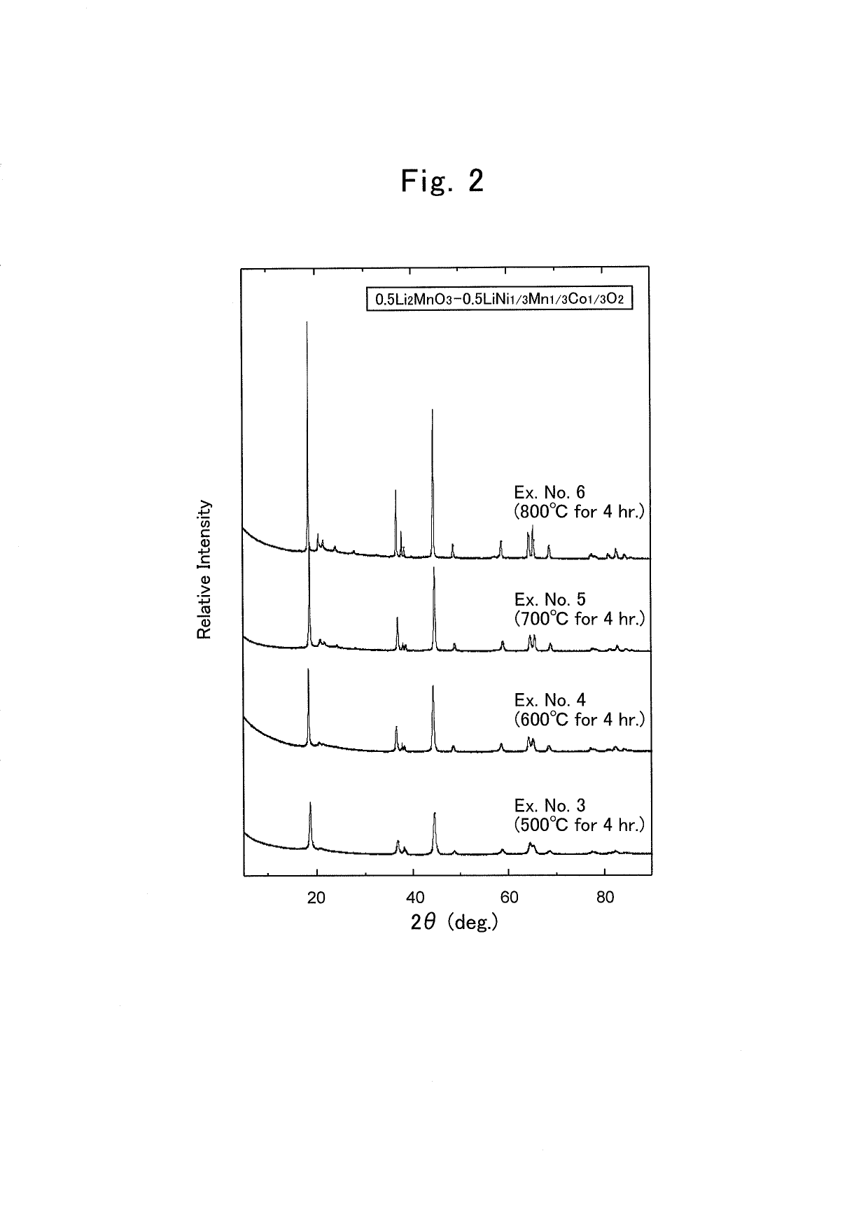

The XRD measurement, in which the CuKα ray was used, was carried out for the obtained black-colored powder. The measurement result is shown in FIG. 2. According to the XRD, it was understood that the obtained compound had a layered rock-salt structure. Moreover, according to the ICP and average valence analysis of Mn, it was ascertained that its composition was 0.5(Li₂MnO₃) 0.5(LiCo_{1/3}Ni_{1/3}Mn_{1/3}O₂).

### Example Nos. 4 Through 6

### Synthesis of 0.5(Li₂MnO₃).0.5(LiCo_{1/3}Ni_{1/3}Mn_{1/3}O₂)

Other than altering the heating temperature for the raw-material mixture, respectively, each 0.5(Li₂MnO₃).0.5(LiCo_{1/3}Ni_{1/3}Mn_{1/3}O₂) was synthesized in the same manner as Example No. 3. To be concrete, although the raw-material mixture was heated to 500° C. in Example No. 3, it was heated to 600° C. in Example No. 4, to 700° C. in Example No. 5, and to 800° C. in Example No. 6, respectively.

The XRD measurement, in which the CuKα ray was used, was carried out for the obtained black-colored powders, respectively. The measurement results are shown in FIG. 2. According to the XRD, it was understood that the obtained compound had a layered rock-salt structure in any of Example Nos. 4 through 6, respectively. Moreover, according to the ICP and average valence analysis of Mn, it was ascertained that its composition was 0.5(Li₂MnO₃).0.5(LiCo_{1/3}Ni_{1/3}Mn_{1/3}O₂) in any of them, respectively.

### Example No. 7

0.5(Li₂MnO₃).0.5(LiCo_{1/3}Ni_{1/3}Mn_{1/3}O₂), which had been obtained in Example No. 3, was heat treated (or calcined) by an electric furnace at 700° C. for 6 hours in an oxygen atmosphere with 100%-by-volume pure oxygen.

### Example No. 8

### Synthesis of LiCo_{1/3}Ni_{1/3}Mn_{1/3}O₂

0.30-mol (i.e., 12.6-gram) lithium hydroxide monohydrate, LiOH.H₂O, which served as a molten-salt raw material, was mixed with a 1.0-gram precursor, which served as a metallic-compound raw material, to prepare a raw-material mixture. Hereinafter, a synthesis procedure for the precursor will be explained.

0.16-mol (i.e., 45.9-gram) Mn(NO₃)₂.6H₂O, 0.16-mol (i.e., 46.6-gram) Co(NO₃)₂.6H₂O, and 0.16-mol (i.e., 46.5-gram) Ni(NO₃)₂.6H₂O were dissolved in 500-mL distilled water to make a metallic-salt-containing aqueous solution. While this aqueous solution was stirred within an ice bath using a stirrer, one in which 50-gram (i.e., 1.2-mol) LiOH.H₂O had been dissolved in 300-mL distilled water was dropped to the aqueous solution over a time period of 2 hours to alkalify it, thereby precipitating deposits of metallic compounds. While keeping this solution holding deposits therein at 5° C., aging was carried out for one day in an oxygen atmosphere. A precursor with Mn:Co:Ni=0.16:0.16:0.16 was obtained by means of filtering the obtained deposits and then washing them with use of distilled water.

Note that it was ascertained by means of the X-ray diffraction measurement that the obtained precursor comprised a mixed phase between Mn₃O₄, Co₃O₄ and NiO. Consequently, a content of transition metal oxides was 0.013 mol in 1 gram of this precursor. On this occasion, let us assume that the transition metals in the precursor were supplied completely to the resulting targeted product, then, the ratio, namely, (Li in Targeted Product)/(Li in Molten-salt Raw Material), was 0.013 mol/0.3 mol=0.043.

The raw-material mixture was put in a crucible, and was then vacuum dried by a vacuum drier at 120° C. for 12 hours. Thereafter, the drier was returned back to the atmospheric pressure; the crucible, in which the raw-material mixture was held, was taken out and was then transferred immediately into an electric furnace, which had been heated to 700° C., and was further heated at 700° C. for 2 hours in an oxygen atmosphere (e.g., in pure oxygen by 100% by volume). On this occasion, the raw-material mixture was fused to turn into a molten salt, and thereby a black-colored product deposited.

Next, the crucible, in which the molten salt was held, was taken out from the electric furnace, and was then cooled at room temperature. After the molten salt was cooled fully to solidify, the solidified molten salt was dissolved in water by immersing the molten salt as being held in the crucible into 200-ml, ion-exchanged water and then stirring them therein. Since the black-colored product was insoluble in water, the water turned into a black-colored suspension liquid. When filtering the black-colored suspension liquid, a transparent filtrate was obtained, and a black-colored, solid filtered substance was obtained on the filter paper. The obtained filtered substance was further filtered while washing it fully with use of ion-exchanged water. After vacuum drying the post-washing black-colored solid at 120° C. for 6 hours, it was pulverized using a mortar and pestle.

The XRD measurement, in which the CuKα ray was used, was carried out for the obtained black-colored powder. The measurement result is shown in FIG. 2. According to the XRD, it was understood that the obtained compound had a layered rock-salt structure. Moreover, according to the ICP and average valence analysis of Mn, it was ascertained that its composition was LiCo_{1/3}Ni_{1/3}Mn_{1/3}O₂.

### Reference Example No. 1

### Synthesis of Li₂MnO₃

0.15-mol (i.e., 6.3-gram) lithium hydroxide monohydrate, LiOH.H₂O, was mixed with 0.10-mol (i.e., 6.9-gram) lithium nitrate, LiNO₃, to prepare a molten-salt raw material. To this, 0.010-mol (i.e., 0.87-gram) manganese dioxide, MnO₂, was added as a metallic-compound raw material, thereby preparing a raw-material mixture. On this occasion, let us assume that Mn in the manganese dioxide was supplied completely to the resulting targeted product, then, the ratio, namely, (Li in Targeted Product)/(Li in Molten-salt Raw Material), was 0.020 mol/0.25 mol=0.08.

The raw-material mixture was put in a crucible, and was then vacuum dried inside a vacuum drier at 120° C. for 12 hours. Thereafter, the drier was returned back to the atmospheric pressure; the crucible, in which the raw-material mixture was held, was taken out and was then transferred immediately into an electric furnace, which had been heated to 350° C., and was further heated at 350° C. for hours in an oxygen atmosphere in which an oxygen concentration was 100%. On this occasion, the raw-material mixture was fused to turn into a molten salt, and thereby a black-colored product deposited.

Next, the crucible, in which the molten salt was held, was taken out from the electric furnace, and was then cooled at room temperature. After the molten salt was cooled fully to solidify, the solidified molten salt was dissolved in water by immersing the molten salt as being held in the crucible into 200-mL ion-exchanged water and then stirring them therein. Since the black-colored product was insoluble in water, the water turned into a black-colored suspension liquid. When filtering the black-colored suspension liquid, a transparent filtrate was obtained, and a black-colored, solid filtered substance was obtained on the filter paper. The obtained filtered substance was further filtered while washing it fully with use of ion-exchanged water. After vacuum drying the post-washing black-colored solid at 120° C. for 6 hours, it was pulverized using a mortar and pestle.

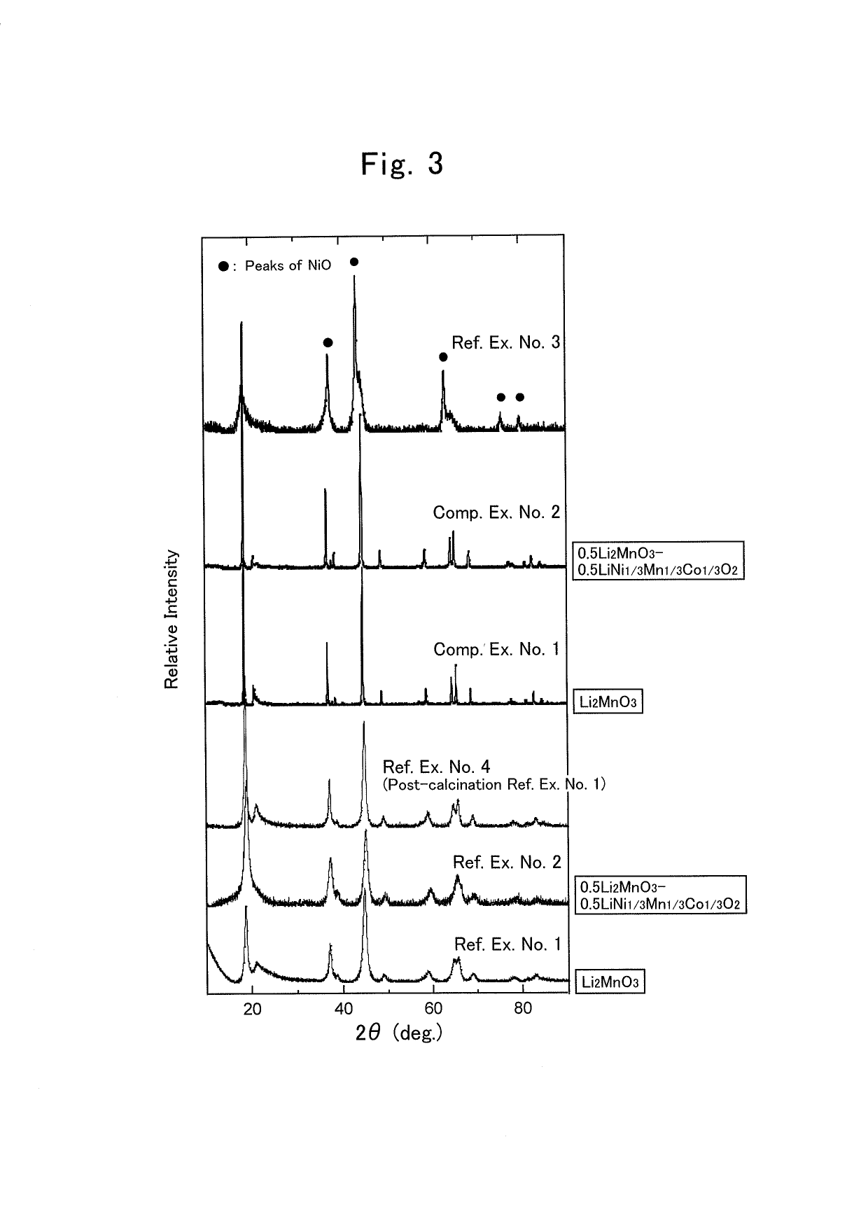

The X-ray diffraction (or XRD) measurement, in which the CuKα ray was used, was carried out for the obtained black-colored powder. The measurement result is shown in FIG. 3. According to the XRD, it was understood that the obtained compound had a layered rock-salt structure. Moreover, according to the oxidation-reduction titration, the average valence analysis of Mn was done. In addition, according to the result of the average valence analysis as well as the emission spectroscopic (e.g., ICP) analysis, it was ascertained that an obtained composition was Li₂MnO₃.

### Reference Example No. 2

### Synthesis of 0.5(Li₂MnO₃).0.5(LiCo_{1/3}Ni_{1/3}Mn_{1/3}O₂)

A mixed phase of Li₂MnO₃ and LiCo_{1/3}Ni_{1/3}Mn_{1/3}O₂ was synthesized by means of the following procedure.

0.30-mol (i.e., 12.6-gram) lithium hydroxide monohydrate, LiOH.H₂O, was mixed with 0.10-mol (i.e., 6.9-gram) lithium nitrate, LiNO₃, to prepare a molten-salt raw material. To this, a precursor was added as a metallic-compound raw material in an amount of 1.0 g to prepare a raw-material mixture. Hereinafter, a synthesis procedure for the precursor will be explained.

0.67-mol (i.e., 192.3-gram)Mn(NO₃)₂.6H₂O, 0.16-mol (i.e., 46.6-gram) Co(NO₃)₂.6H₂O, and 0.16-mol (i.e., 46.5-gram) Ni(NO₃)₂.6H₂O were dissolved in 500-mL distilled water to make a metallic-salt-containing aqueous solution. While this aqueous solution was stirred within an ice bath using a stirrer, one in which 50-gram (i.e., 1.2-mol) LiOH.H₂O had been dissolved in 300-mL distilled water was dropped to the aqueous solution over a time period of 2 hours to alkalify it, thereby precipitating deposits of metallic hydroxides. While keeping this solution holding deposits therein at 5° C., aging was carried out for one day in an oxygen atmosphere. A precursor with Mn:Co:Ni=0.67:0.16:0.16 was obtained by means of filtering the obtained deposits and then washing them with use of distilled water.

Note that it was ascertained by means of the X-ray diffraction measurement that the obtained precursor comprised a mixed phase between Mn₃O₄, CO₃O₄ and NiO. Consequently, a content of transition metal elements was 0.013 mol in 1 gram of this precursor. On this occasion, let us assume that the transition metals in the precursor were supplied completely to the resulting targeted product, then, the ratio, namely, (Li in Targeted Product)/(Li in Molten-salt Raw Material), was 0.0195 mol/0.4 mol=0.04875.

The raw-material mixture was put in a crucible, and was then vacuum dried at 120° C. for 12 hours inside a vacuum drier. Thereafter, the drier was returned back to the atmospheric pressure; the crucible, in which the raw-material mixture was held, was taken out and was then transferred immediately into an electric furnace, which had been heated to 450° C., and was further heated at 450° C. for 4 hours in an oxygen atmosphere. On this occasion, the raw-material mixture was fused to turn into a molten salt, and thereby a black-colored product deposited.

Next, the crucible, in which the molten salt was held, was taken out from the electric furnace, and was then cooled at room temperature. After the molten salt was cooled fully to solidify, the solidified molten salt was dissolved in water by immersing the molten salt as being held in the crucible into 200-mL ion-exchanged water and then stirring them therein. Since the black-colored product was insoluble in water, the water turned into a black-colored suspension liquid. When filtering the black-colored suspension liquid, a transparent filtrate was obtained, and black-colored, solid filtered substance was obtained on the filter paper. The obtained filtered substance was further filtered while washing it fully with use of ion-exchanged water. After vacuum drying the post-washing black-colored solid at 120° C. for 6 hours, it was pulverized using a mortar and pestle. The X-ray diffraction measurement, in which the CuKα ray was used, was carried out for the obtained black-colored powder. The measurement result is shown in FIG. 3. According to the XRD, it was understood that the obtained compound had a layered rock-salt structure. Moreover, according to the ICP and analysis on an average valence of Mn, it was ascertained that the composition was 0.5(Li₂MnO₃).0.5 (LiCo_{1/3}Ni_{1/3}Mn_{1/3}O₂).

### Reference Example No. 3

0.30-mol (i.e., 12.6-gram) lithium hydroxide monohydrate, LiOH, H₂O, was mixed with 0.10-mol (i.e., 6.9-gram) lithium nitrate, LiNO₃, to prepare a molten-salt raw material. To this, the following, which served as metallic-compound raw materials, were added, thereby preparing a raw-material mixture: 0.0067-mol (i.e., 0.58-gram) MnO₂; 0.0016-mol (i.e., 0.12-gram) CoO; and 0.0016-mol (i.e., 0.12-gram) NiO. On this occasion, let us assume that the transition metals in the metallic-compound raw material were supplied completely to the resulting targeted product, then, the ratio, namely, (Li in Targeted Product)/(Li in Molten-salt Raw Material), was 0.01485 mol/0.4 mol=0.037125.

The raw-material mixture was put in a crucible, and then a black-colored oxide was obtained by the same procedure as that of Reference Example No. 2 via the following: drying the raw-material mixture; melting the raw-material mixture; cooling the resulting molten salt; dissolving the molten salt; separating the resultant product by means of filtration; and washing and drying the product.

The X-ray diffraction measurement was carried out for the thus obtained black-colored powder. The measurement result is shown in FIG. 3. According to the XRD, it was understood that the obtained black-colored powder had a layered rock-salt structure in which NiO mingled into Li₂MnO₃.LiCoO₂ inadvertently, a manganese.lithium cobaltate mixed phase.

That is, it was understood that, in a case where composite oxides containing Ni are synthesized, it is necessary to employ compounds, which include Ni, as a precursor, respectively, as done in Example Nos. 3 through 6 and 8, and in Reference Example No. 2.

### Reference Example No. 4

The XRD measurement was similarly carried out also for one which was made by calcining the Li₂MnO₃, which had been obtained in Reference Example No. 1, with an electric furnace at 400° C. for 1 hour in air. The measurement result is shown in FIG. 3.

### Comparative Example No. 1

### Synthesis of Li₂MnO₃

0.10-mol (i.e., 4.2-gram) lithium hydroxide monohydrate, LiOH.H₂O, was mixed with 0.025-mol (i.e., 2.18-gram) manganese dioxide, MnO₂, with use of a mortar, thereby preparing a raw-material mixture.

The raw-material mixture was put in an alumina crucible, and then tentative calcination was carried out at 500° C. for 5 hours. The resulting post-tentative-calcination powder was finally calcined at 800° C. for 10 hours after pulverizing it with use of another mortar.

The X-ray diffraction measurement was carried out for the resulting post-final-calcination powder. The measurement result is shown in FIG. 3. According to the XRD, it was understood that the obtained lithium manganate was Li₂MnO₃ that had a layered rock-salt structure.

### Comparative Example No. 2

### Synthesis of 0.5(Li₂MnO₃).0.5(LiCo_{1/3}Ni_{1/3}Mn_{1/3}O₂)

Other than adding 0.5-gram LiOH.H₂O to 1.6-gram calcined precursor substance being made by further calcining the precursor, which had been synthesized in Example No. 3, at 400° C. for 2 hours in air, and then mixing them one another, 0.5(Li₂MnO₃).0.5(LiCo_{1/3}Ni_{1/3}Mn_{1/3}O₂) was synthesized in the same manner as Comparative Example No. 1. The X-ray diffraction measurement was carried out for the resulting post-final-calcination powder. The measurement result is shown in FIG. 3. According to the XRD, ICP and analysis on an average valence of Mn, it was understood that the obtained compound was 0.5(Li₂MnO₃).0.5(LiCo_{1/3}Ni_{1/3}Mn_{1/3}O₂) that had a layered rock-salt structure.

### On Cooling Rate

Even in any of the synthesizing procedures according to the respective examples and respective reference examples, the molten salts had became 200° C. in 2 hours approximately since the cooling begun. That is, the rate of cooling was from 3 to 5° C./minute approximately.

### Particle Diameters of Primary Particles

Regarding the composite oxides according to Example Nos. 1-1, 2-1 and 3 through 6, and regarding those according to Reference Example Nos. 1, 2 and 4, their c-axis-direction particle diameters were calculated, with use of the Scherrer equation, from the (001) peak in each of Li₂MnO₃ at around 18.7 degrees in the XRD patterns. The results are given in Table 1.

Note that, regarding the composite oxide powders according to Example Nos. 3 through 6, and regarding those according to comparative examples, an observation on their primary particles was carried out by means of a scanning electron microscope (or SEM). Since compounds with layered structures are likely to grow as a plate shape, respectively; and since they orient to grow in the directions of the a- and b-axes in this instance, it is anticipated that the thickness-wise direction of the resulting plate-shaped particles could be the c-axis direction. As a result, as to the composite oxides according to Example Nos. 3 through 6, their c-axis-direction sizes, which were calculated from the results of the XRD, coincided substantially with their primary particles' sizes in the could-be c-axis direction. Accordingly, it was suggested that the obtained particles can be single crystalline. Moreover, from their electron diffraction patterns (not shown) as well, regular diffraction points showing the characteristic of single crystal were observed.

### Lithium Secondary Battery

The composite oxide according to Example Nos. 3 through 8 were used as a positive-electrode active material, respectively, thereby making a lithium secondary battery.

The following were mixed one another in a proportion of 50:40:10 by mass ratio: any one of the composite oxides according to Example Nos. 1-2 and 1-3 and those according to Example Nos. 3 through 8; acetylene black serving as a conductive additive; and polytetrafluoroethylene (or PTFE) serving as a binding material. Subsequently, this mixture was press bonded onto an aluminum mesh, namely, a current collector. Thereafter, the mixture on the aluminum mesh was vacuum dried at 120° C. for 12 hours or more, and was then made into an electrode, namely, a positive electrode with φ 14 mm. Metallic lithium with φ 14 mm and 400 μm in thickness was made into a negative electrode to be faced to the positive electrode.

Microporous polyethylene films with 20 μm in thickness serving as separators were held between the positive electrodes and the negative electrodes to make them into an electrode-assembly battery. This electrode-assembly battery was accommodated in a battery case (e.g., CR2032, a coin cell produced by HOHSEN Co., Ltd.). Moreover, a non-aqueous electrolyte, in which LiPF₆ was dissolved in a concentration of 1.0 mol/L into a mixed solvent in which ethylene carbonate and ethyl methyl carbonate were mixed in a volumetric ratio of 1:2, was injected into the battery case, thereby obtaining a lithium secondary battery.

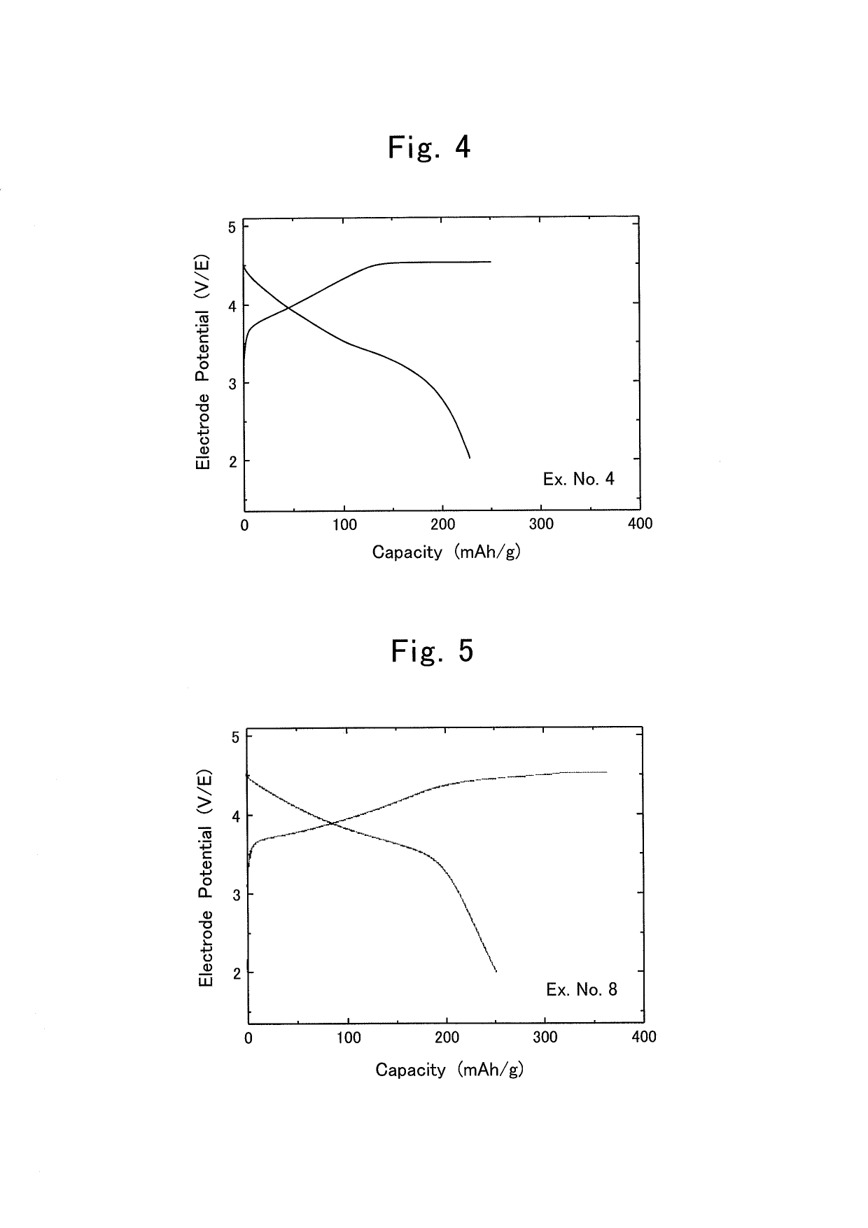

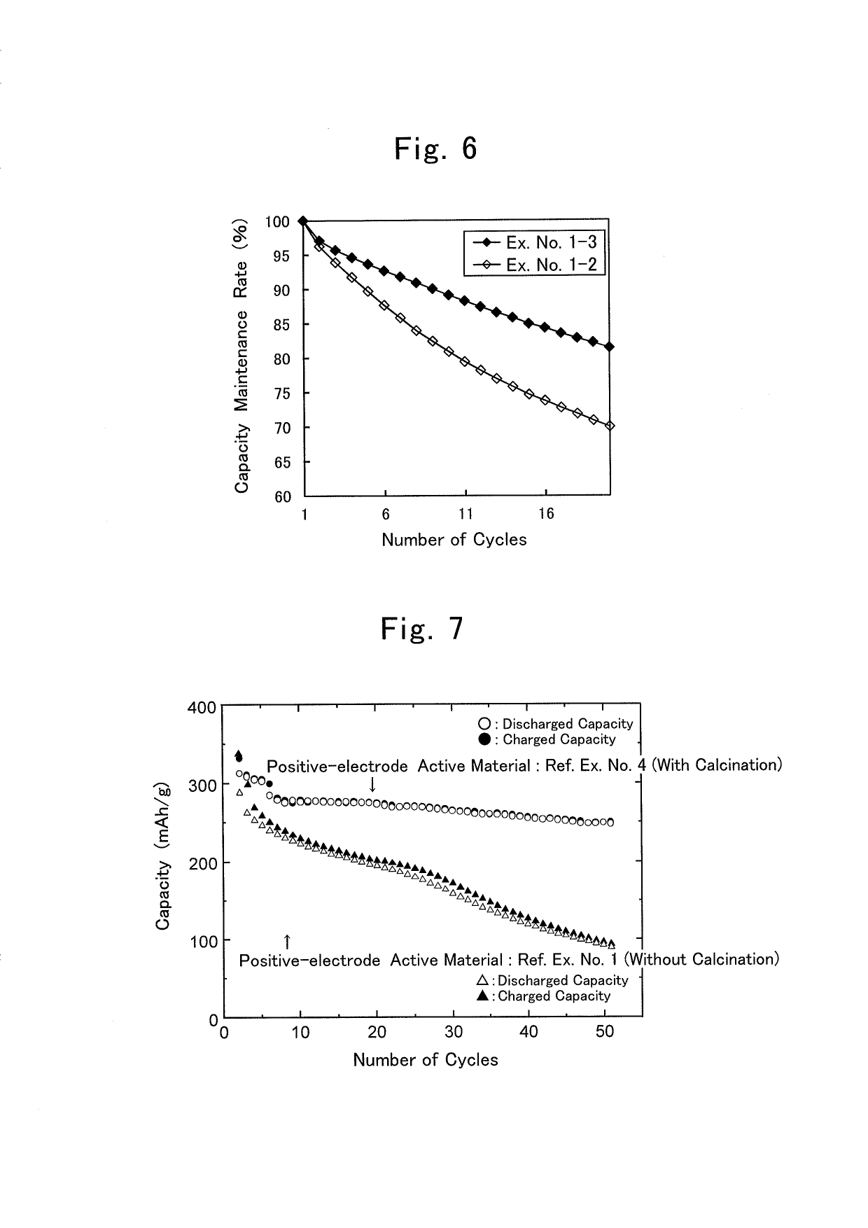

Using the thus made lithium secondary batteries, a charging/discharging test was carried out under a constant temperature, namely, at 25° C. In the charging, a constant-current charging operation was carried out up to 4.5 V at a rate of 0.2 C; thereafter, another charging operation was carried out at a constant voltage of 4.5 V down to a current value of 0.02 C. In the discharging, a discharging operation was carried out down to 2.0 V at a rate of 0.2 C. However, as to the secondary batteries in which the composite oxides according to Example Nos. 1-2 and 1-3 were used, a cut-off voltage at the time of charging was set at 4.6 V. Regarding the composite oxides according to Example Nos. 3 through 8, their first-round discharged capacities are given in Table 1. Moreover, regarding the composite oxides according to Example No. 4 and Example No. 8, their charging/discharging curves are illustrated in FIG. 4 and FIG. 5, respectively. As to the secondary batteries in which the composite oxides according to Example Nos. 1-2 and 1-3 were used, their capacity maintenance rates at the respective cycles (i.e., the “n”th-time-cycle discharged capacity with respect to the first-time-cycle discharged capacity) are illustrated in FIG. 6.

### Lithium Secondary Batteries According to Reference Examples

As reference examples showing an advantageous effect that resulted from carrying out calcination after the synthesis of composite oxide, Li₂MnO₃, the two composite oxides that had been obtained in Reference Example No. 1 and Reference Example No. 4, were used as a positive-electrode active material, respectively, thereby making a lithium secondary battery.

The following were mixed one another: 90-part-by-mass Li₂MnO₃ serving as a positive-electrode active material; 5-part-by-mass carbon black (or KB) serving as a conductive additive; and 5-part-by-mass polyvinylidene fluoride serving as a binding agent (or binder), and then they were dispersed in N-methyl-2-pyrolidone serving as a solvent, thereby preparing a slurry. Subsequently, this slurry was coated onto an aluminum foil, namely, a current collector, and was then dried thereon. Thereafter, the coated aluminum foil was press rolled to 60 μm in thickness, and was then punched out to a size of φ 11 mm in diameter, thereby obtaining a positive electrode. Moreover, metallic lithium with φ 14 mm and 200 μm in thickness was made into a negative electrode to be faced to the positive electrode.

Microporous polyethylene films with 20 μm in thickness serving as separators were held between the positive electrodes and the negative electrodes to make them into an electrode-assembly battery. This electrode-assembly battery was accommodated in a battery case (e.g., CR2032, a coin cell produced by HOHSEN Co., Ltd.). Moreover, a non-aqueous electrolyte, in which LiPF₆ was dissolved in a concentration of 1.0 mol/L into a mixed solvent in which ethylene carbonate and diethyl carbonate were mixed in a volumetric ratio of 3:7, was injected into the battery case, thereby obtaining a lithium secondary battery.

Regarding the lithium secondary batteries according to the reference examples, a charging/discharging test was carried out at room temperature for 50 cycles. In the charging/discharging test, a CCCV charging (i.e., constant-current and constant-voltage charging) operation was carried out up to 4.6 V at 0.2 C, and then a CC discharging operation was carried out down to 2.0 V at 0.2 C. After the second cycle and later on, the following charging and discharging operations were carried out repeatedly: a CCCV charging (i.e., constant-current and constant-voltage charging) operation was carried out up to 4.6 V at 0.2 C; and a CC discharging operation was carried out down to 2.0 V at 0.2 C. Note that a condition for terminating the constant-voltage charging operation was set at an electric-current value of 0.02 C. The charged and discharged capacities at the respective cycles are illustrated in FIG. 7.

TABLE 1

| | | | c-axis-direction | |
|---|---|---|---|---|
| | | Temperature of | Particle Diameter | |
| | | Molten Salt | Calculated from | First-round |
| | | (i.e., Reaction | the Scherrer | Discharged |
| | Type of Composite Oxide | Temperature) (° C.) | Equation (nm) | Capacity (mAh/g) |
| Example No. 1-1 | Li₂MnO₃ | 700 | 94.7 | — |
| Example No. 2-1 | Li₂MnO₃ | 700 | 81.2 | — |
| Example No. 3 | Li₂MnO₃—LiCo_{1/3}Ni_{1/3}Mn_{1/3}O₂ | 500 | 22.5 | 217 |
| Example No. 4 | Li₂MnO₃—LiCo_{1/3}Ni_{1/3}Mn_{1/3}O₂ | 600 | 41.8 | 229 |
| Example No. 5 | Li₂MnO₃—LiCo_{1/3}Ni_{1/3}Mn_{1/3}O₂ | 700 | 52.4 | 176 |
| Example No. 6 | Li₂MnO₃—LiCo_{1/3}Ni_{1/3}Mn_{1/3}O₂ | 800 | 75.0 | 160 |
| Example No. 7 | Li₂MnO₃—LiCo_{1/3}Ni_{1/3}Mn_{1/3}O₂ | — | — | 240 |
| (After | | | | |
| Calcination) | | | | |
| Example No. 8 | LiCo_{1/3}Ni_{1/3}Mn_{1/3}O₂ | 700 | — | 251 |
| Reference | Li₂MnO₃ | 350 | 12.3 | — |
| Example No. 1 | | | | |
| Reference | Li₂MnO₃—LiCo_{1/3}Ni_{1/3}Mn_{1/3}O₂ | 450 | 8.2 | — |
| Example No. 2 | | | | |
| Reference | Li₂MnO₃ | — | 13.3 | — |
| Example No. 4 | | | | |
| (After | | | | |
| Calcination) | | | | |
| Comparative | Li₂MnO₃ | (Being Calcined | 1000 or more | — |
| Example No. 1 | | at 800° C. for 10 | | |
| | | hours) | | |
| Comparative | Li₂MnO₃—LiCo_{1/3}Ni_{1/3}Mn_{1/3}O₂ | (Being Calcined | 1000 or more | — |
| Example No. 2 | | at 800° C. for 10 | | |
| | | hours) | | |

The respective comparative examples were found to have a particle diameter of 12 μm approximately according to a result of measuring the thickness of a plurality of their particles from the SEM images.

The composite oxides being obtained in Comparative Example Nos. 1 and 2 were very large particles whose particle diameter exceeded 10 μm, respectively. However, since the diffraction peak (FIG. 3), which is seen at around 2θ=63 degrees, is separated into two elements, it was understood that their crystallinity is high.

In the reference examples, since the molten salts including LiNO₃ were employed, the temperature of the resulting molten salts could only be raised up to no more than 500° C. approximately. This is because the decomposition temperature of LiNO₃ is about 550° C. In Reference Example No. 1 and Reference Example No. 2, extremely-fine composite oxides were obtained, because the temperatures of the resulting molten salt (i.e., the reaction temperatures) were a low temperature, respectively. However, since the diffraction peaks (FIG. 3), which are seen at around 2θ=63 degrees, are not separated, it was understood that their crystallinity is low. That is, in the case where a molten salt including LiNO₃ was employed, no sufficient reaction occurred, so that it was difficult to obtain composite oxides which were of high crystallinity.

In the composite oxides being synthesized in Example No. 1-1 and Example No. 2-1, since the diffraction peaks (FIG. 1), which are seen at around 2θ=63 degrees, are separated into two elements, it was understood that their crystallinity is high. Moreover, in the composite oxides being obtained in Example Nos. 1-1 and No. 2-1, although the reaction temperature was high, their particle diameters could be kept down to 100 nm or less.

In Example Nos. 3 through 6, the composite oxides were synthesized while setting the temperatures of the resulting molten salt to fall in a range of from 500 to 800° C. It was possible to keep down their particle diameters to 100 nm or less, although the higher the reaction temperature became the greater the resultant particle diameter became. Moreover, it was understood from FIG. 2 that the higher the reaction temperature becomes the higher the crystallinity becomes. Since the first-round discharged capacity of the composite oxide being synthesized in Example No. 4 was the highest, it is presumed that the crystallinity and a particle diameter being suitable for charging and discarding can be compatible with each other by means of setting the reaction temperature at 600° C. approximately, to be concrete, setting it at from 550 to 650° C.

Moreover, it was understood that the presence or absence of calcination after synthesizing the composite oxides greatly affects the resulting characteristics as secondary battery. To be concrete, with regard to the capacity maintenance rate, the secondary battery, in which the composite oxide according to Example No. 1-3 was used as the positive-electrode active material, was higher than was the other secondary battery, in which the composite oxide according to Example No. 1-2 was used as the positive-electrode active material. Since the difference between Example No. 1-2 and Example No. 1-3 lies only in the presence or absence of calcination after synthesizing the composite oxides, it was understood that the resultant characteristics as secondary battery upgrade greatly by means of subjecting them to calcination. Moreover, Example No. 7 is one which was made by calcining the composite oxide being obtained in Example No. 3 in air. It was understood from Table 1 that the first-round discharged capacity was augmented by means of calcining the composite oxide being obtained in Example No. 3.

These results are results that suggest the following: LiOH, which had been included as an impurity in the resulting product before calcination, was decomposed by means of the calcination; and the Li deficiency in the resultant composite oxide was compensated as being accompanied by the decomposition reaction that resulted from the calcination.

Incidentally, Reference Example No. 4 is one which was made by calcining the composite oxide being obtained in Reference Example No. 1 in air. It was understood from FIG. 3 that the crystallinity was enhanced by means of doing calcination. Moreover, from FIG. 7, the secondary battery, in which the composite oxide being obtained in Reference Example No. 4 was used as the positive-electrode active material, could retain the initial discharged capacity even after 50 cycles of charging and discharging operations, in comparison to Reference Example No. 1. That is, in a composite oxide being subjected to calcination after synthesizing the composite oxide, it is possible to say that the resulting cyclability upgrades greatly. This result suggests that, in composite oxides with high crystallinity (namely, the composite oxides being obtained by means of the production process according to the present invention), the resultant cyclability is enhanced.

From those above, it was understood that the highly-crystalline composite oxides, which are obtainable by means of the production process according to the present invention, exhibit excellent characteristics as a positive-electrode active material for secondary battery. In addition, it was understood that not only impurities, such as LiOH, are decomposed, but also the Li deficiency in these composite oxides are compensated, by means of calcining the composite oxides, so that further upgrades can be brought about in the resulting battery characteristics.

1. A production process for composite oxide being characterized in that:
it is a production process for composite oxide, production process whose a major product is a lithium-manganese-based oxide that includes at least the following: a lithium (Li) element; and a tetravalent manganese (Mn) element, and lithium-manganese-based oxide whose crystal structure belongs to a layered rock-salt structure;
said composite oxide is obtained via the following:
a molten reaction step of reacting at least the following one another: a metal-containing raw material; and a molten-salt raw material at a melting point of the molten-salt raw material or more,
the metal-containing raw material including one or more kinds of metallic elements in which Mn is essential,
the molten-salt raw material including lithium hydroxide but not including any other compound virtually, and the molten-salt raw material including Li in an amount that exceeds a theoretical composition of Li being included in said composite oxide to be targeted; and
a recovery step of recovering said composite oxide being generated at said molten reaction step.

2. The production process for composite oxide as set forth in claim 1, wherein said recovery step is a step of recovering said composite oxide after cooling said molten-salt raw material, which has been melted at said molten reaction step, gradually.

3. The production process for composite oxide as set forth in claim 2, wherein said recovery step is a step of cooling said molten-salt raw material, which has been melted at said molten reaction step, gradually at a rate of from 2° C./minute or more to 50° C./minute or less.

4. The production process for composite oxide as set forth in claim 1, wherein said molten reaction step is carried out in an oxygen-containing atmosphere.

5. The production process for composite oxide as set forth in claim 1, wherein said molten reaction step is a step of reacting said metal-containing raw material and said molten-salt raw material one another at from 500° C. or more to 900° C. or less.

6. The production process for composite oxide as set forth in claim 5, wherein said molten reaction step is a step of reacting said metal-containing raw material and said molten-salt raw material one another at 550° C. or more.

7. The production process for composite oxide as set forth in claim 1, wherein said metal-containing raw material includes a first metallic compound including one or more kinds of metallic elements in which Mn is essential, and the metal-containing raw material further includes a second metallic compound including one or more kinds of metallic elements from which Mn is excluded, if needed.

8. The production process for composite oxide, wherein a precursor synthesis step, in which an aqueous solution including at least two kinds of metallic elements is alkalified in order to obtain precipitates, is further carried out before the molten reaction step in the production process for composite oxide as set forth in claim 1, and then said metal-containing raw material including the precipitates is employed at the molten reaction step.

9. The production process for composite oxide as set forth in claim 1, wherein a ratio, the theoretical composition of Li being included in said composite oxide to be targeted with respect to Li being included in said molten-salt raw material (i.e., (Li in Composite Oxide)/(Li in Molten-salt Raw Material)), falls in a range of from 0.02 or more to 0.7 or less by molar ratio.

10. The production process for composite oxide as set forth in claim 1, wherein the lithium hydroxide being included in said molten-salt raw material is in a state of being dehydrated.

11. The production process for composite oxide being characterized in that a heat-calcination treatment step, in which said composite oxide is heated, is further carried out after the recovery step in the production process for composite oxide as set forth in claim 1.

12. The production process for composite oxide as set forth in claim 11, wherein said heat-calcination treatment step is carried out in an oxygen-containing atmosphere.

13. A positive-electrode active material for secondary battery being characterized in that it includes the composite oxide that has been obtained by means of the production process for composite oxide as set forth in claim 1.

14. The positive-electrode active material for secondary battery as set forth in claim 13, wherein said composite oxide comprises single-crystalline primary particles.

15. The positive-electrode active material for secondary battery as set forth in claim 13, wherein said composite oxide comprises, as a basic composition, a lithium-manganese-based oxide being expressed by a compositional formula: xLi₂M¹O₃.(1−x)LiM²O₂ (where “x” satisfies 0≦“x”≦1; “M¹” is one or more kinds of metallic elements in which tetravalent Mn is essential; “M²” is one or more kinds of metallic elements; and Li may even be substituted by hydrogen in a part thereof in any of the cases).

16. The positive-electrode active material for secondary battery as set forth in claim 13, wherein said composite oxide comprises, as a basic composition, a lithium-manganese-based oxide being expressed by a compositional formula: Li_{1.33-y}M¹_{0.67-z}M²_{y+z}O₂ (where “M¹” is one or more kinds of metallic elements in which tetravalent Mn is essential; “M²” is one or more kinds of metallic elements; 0≦“y”≦0.33; 0≦“Z”≦0.67; and Li may even be substituted by hydrogen in a part thereof).

17. A secondary battery being characterized in that it is equipped with:
a positive electrode including the positive-electrode active material for secondary battery as set forth in claim 13;
a negative electrode; and
a non-aqueous electrolyte.

18. A vehicle being characterized in that it has the secondary battery as set forth in claim 17 on-board.
